(19) United States
(12) Patent Application Publication
(10) Pub. No.: US 2024/0004301 A1
(43) Pub. Date: Jan. 4, 2024

(54) SUBSTRATE PROCESSING APPARATUS, SUBSTRATE PROCESSING METHOD, AND RECORDING MEDIUM

(71) Applicant: Tokyo Electron Limited, Tokyo (JP)

(72) Inventor: Yoshitomo Sato, Koshi City (JP)

(21) Appl. No.: 18/318,041

(22) Filed: May 16, 2023

(30) Foreign Application Priority Data
May 18, 2022 (JP) 2022-081813
Feb. 8, 2023 (JP) 2023-017597

(51) Int. Cl. G03F 7/30; C23C 16/54; C23C 16/02

(52) U.S. Cl. CPC G03F 7/305; C23C 16/0227; C23C 16/54

(57) ABSTRACT

A substrate processing apparatus includes a film processing unit configured to perform a preset processing including formation of a resist film on a front surface of a substrate; and a carry-in/out unit configured to perform a carry-in/carry-out of the substrate into/from the film processing unit. The film processing unit includes a resist film forming unit configured to form the resist film on the front surface of the substrate; a film removing unit configured to supply, to a rear surface film formed on a rear surface of the substrate opposite to the front surface, a processing liquid configured to remove the rear surface film; and a foreign substance removing unit configured to move a brush along the rear surface of the substrate, while keeping the brush in contact with the rear surface of the substrate after being processed by the film removing unit.

### CROSS-REFERENCE TO RELATED APPLICATION

This application claims the benefit of Japanese Patent Application Nos. 2022-081813 and 2023-017597 filed on May 18, 2022 and Feb. 8, 2023, respectively, the entire disclosures of which are incorporated herein by reference.

### TECHNICAL FIELD

The various aspects and exemplary embodiments described herein pertain generally to a substrate processing apparatus, a substrate processing method, and a recording medium.

### BACKGROUND

Patent Document 1 describes a substrate processing method of removing a target object on a rear surface of a substrate.

Patent Document 1: Japanese Patent Laid-open Publication No. 2013-021026

### SUMMARY

In an exemplary embodiment, a substrate processing apparatus includes a film processing unit configured to perform a preset processing including formation of a resist film on a front surface of a substrate; and a carry-in/out unit configured to perform a carry-in/carry-out of the substrate into/from the film processing unit. The film processing unit includes a film forming unit configured to form the resist film on the front surface of the substrate by supplying a first processing liquid on the front surface of the substrate; a film removing unit configured to supply, to a rear surface film formed on a rear surface of the substrate opposite to the front surface, a second processing liquid configured to remove the rear surface film; and a foreign substance removing unit configured to move a brush along the rear surface of the substrate, while keeping the brush in contact with the rear surface of the substrate after being processed by the film removing unit.

The foregoing summary is illustrative only and is not intended to be any way limiting. In addition to the illustrative aspects, embodiments, and features described above, further aspects, embodiments, and features will become apparent by reference to the drawings and the following detailed description

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a perspective view schematically illustrating an example of a substrate processing system;

FIG. 2 is a side view schematically illustrating an example of a coating and developing apparatus;

FIG. 3 is a side view schematically illustrating an example of a liquid processing unit;

FIG. 4 is a schematic diagram illustrating an example of a cross section of a workpiece having a film formed on a rear surface thereof;

FIG. 5 is a side view schematically illustrating an example of a first rear surface processing unit;

FIG. 6 is a top view schematically illustrating an example of a second rear surface processing unit;

FIG. 7 is a side view schematically illustrating the example of the second rear surface processing unit;

FIG. 8 is a flowchart illustrating an example of a substrate processing method;

FIG. 9 is a flowchart illustrating an example of a foreign substance removing processing;

FIG. 10A and FIG. 1013 are schematic diagrams illustrating an example of a state in which the foreign substance removing processing is being performed;

FIG. 11A and FIG. 11B are schematic diagrams illustrating an example of a state in which the foreign substance removing processing is being performed;

FIG. 12A and FIG. 12B are schematic diagrams illustrating an example of a state in which the foreign substance removing processing is being performed;

FIG. 13 is a side view schematically illustrating an example of a coating and developing apparatus;

FIG. 14 is a flowchart illustrating an example of a substrate processing method;

FIG. 15 is a side view schematically illustrating an example of a coating and developing apparatus;

FIG. 16 is a side view schematically illustrating an example of a polishing unit and a cleaning unit;

FIG. 17 is a side view schematically illustrating an example of a coating and developing apparatus;

FIG. 18 is a side view schematically illustrating an example of a friction reducing film forming unit;

FIG. 19 is a flowchart illustrating an example of a substrate processing method;

FIG. 20A to FIG. 20C are schematic diagrams illustrating a state in which a friction reducing film is being formed; and

FIG. 21 is a flowchart illustrating an example of a substrate processing method.

### DETAILED DESCRIPTION

Hereinafter, exemplary embodiments will be described with reference to the accompanying drawings. In the following description, same parts or parts having same functions will be assigned same reference numerals, and redundant description will be omitted. In some of the drawings, an orthogonal coordinates system defined by the X-axis, the Y-axis and the Z-axis may be used. In the following exemplary embodiments, the Z-axis corresponds to a vertical direction, and the X-axis and the Y-axis correspond to horizontal directions. The positive Z-axis direction corresponds to a vertically upward direction, whereas the negative Z-axis direction corresponds to a vertically downward direction.

### First Exemplary Embodiment

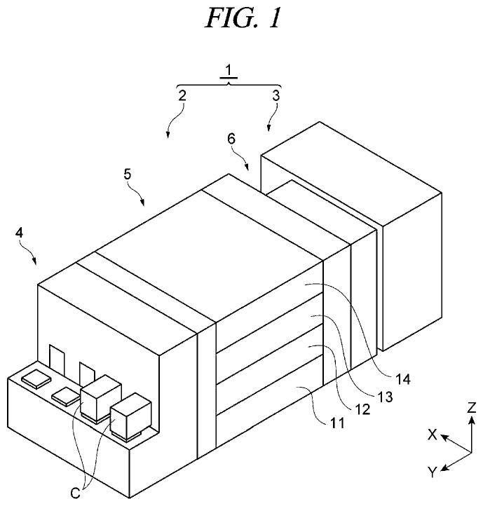

First, referring to FIG. 1 to FIG. 12B, a substrate processing system according to a first exemplary embodiment will be described. A substrate processing system 1 (substrate processing apparatus) shown in FIG. 1 is a system configured to perform, on a workpiece W, formation of a photosensitive film, exposure of the photosensitive film, and development of the photosensitive film. The workpiece Was a target of processing is, for example, a substrate or a substrate having a film or a circuit formed thereon by being subjected to a preset processing. The substrate is, by way of example, a silicon wafer. The workpiece W (substrate) may be of a circular shape. As another example, the workpiece W may be a glass substrate, a mask substrate, or a flat panel display (FPD).

When a bevel (chamfer) is provided at the edge of the workpiece W, a “front surface” of the workpiece W in the present disclosure includes a bevel portion when viewed from the front surface side of the workpiece W, and a “rear surface” of the workpiece W also includes a bevel portion when viewed from the rear surface side of the workpiece W. The front surface of the workpiece W (hereinafter referred to as “front surface Wa”) is, among a pair of main surfaces of the workpiece W, a main surface on which a photosensitive film is formed. The rear surface of the workpiece W (hereinafter referred to as “rear surface Wb”) is a main surface opposite to the front surface Wa among the pair of main surfaces. The photosensitive film is, for example, a resist film.

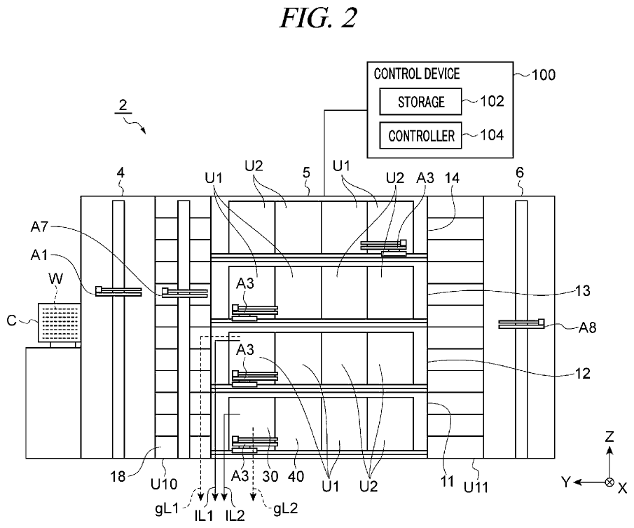

As depicted in FIG. 1 and FIG. 2, the substrate processing system 1 includes a coating and developing apparatus 2, an exposure apparatus 3, and a control device 100. The exposure apparatus 3 is configured to perform an exposure processing for the resist film (photosensitive film) formed on the workpiece W (substrate). To elaborate, the exposure apparatus 3 is configured to radiate an energy ray to an exposure target portion of the resist film by an immersion exposure method or the like. The energy ray may be, for example, ionizing radiation or non-ionizing radiation.

The coating and developing apparatus 2 (substrate processing apparatus) is configured to perform a processing of forming the resist film on the front surface Wa of the workpiece W prior to the exposure processing by the exposure apparatus 3. For example, the coating and developing apparatus 2 forms the resist film on the front surface Wa of the workpiece W by coating a resist on the front surface Wa of the workpiece W. The coating and developing apparatus 2 may perform a developing processing for the resist film after the exposure processing in addition to the processing of forming the resist film. The energy rays are selectively radiated by the exposure apparatus 3 to the exposure target portion of the resist film before the developing processing. The coating and developing apparatus 2 includes, for example, a carrier block 4, a processing block 5, and an interface block 6.

The carrier block 4 is configured to carry the workpiece W into/from the coating and developing apparatus 2. For example, the carrier block 4 is configured to support a plurality of carriers C for workpieces W, and incorporates therein a transfer device A1 having a delivery arm. Each carrier C accommodates therein, for example, a multiple number of workpieces W having a circular shape. The transfer device A1 serves to take out the workpiece W from the carrier C, hand the workpiece W over to the processing block 5, receive the workpiece W from the processing block 5, and return the workpiece W back into the carrier C. As stated above, the carrier block 4 including the transfer device A1 is configured to carry the workpiece W into/from the processing block 5. The processing block 5 includes processing modules 11, 12, 13 and 14.

The processing module 11 incorporates therein a liquid processing unit U1, a heat treatment unit U2, and a transfer device A3 configured to transfer the workpiece W into these units. The processing module 11 is configured to form a bottom film on the front surface Wa of the workpiece W by the liquid processing unit U1 and the heat treatment unit U2. The liquid processing unit U1 is configured to supply a processing liquid for the formation of the bottom film to the front surface Wa of the workpiece W, and coats this processing liquid on the front surface Wa of the workpiece W. The heat treatment unit U2 is configured to perform various kinds of heat treatments required to form the bottom film.

The processing module 12 incorporates therein a liquid processing unit U1, a heat treatment unit U2, and a transfer device A3 configured to transfer the workpiece W into these units. The processing module 12 is configured to form a resist film on the bottom film by the liquid processing unit U1 and the heat treatment unit U2. The liquid processing unit U1 is configured to supply a processing liquid for the formation of the resist film to the front surface Wa of the workpiece W, and coats this processing liquid on the bottom film. The heat treatment unit U2 is configured to perform various kinds of heat treatments required to form the resist film. The liquid processing unit U1 and the heat treatment unit U2 in the processing module 12 function as a resist film forming unit configured to form the resist film on the front surface Wa of the workpiece W.

The processing module 13 incorporates therein a liquid processing unit U1, a heat treatment unit U2, and a transfer device A3 configured to transfer the workpiece W into these units. The processing module 13 is configured to form a top film on the resist film by the liquid processing unit U1 and the heat treatment unit U2. The liquid processing unit U1 is configured to supply a processing liquid for the formation of the top film to the front surface Wa of the workpiece W, and coats this processing liquid on the resist film. The heat treatment unit U2 is configured to perform various kinds of heat treatments required to form the top film.

The processing module 14 incorporates therein a liquid processing unit U1, a heat treatment unit U2, and a transfer device A3 configured to transfer the workpiece W into these units. The processing module 14 is configured to perform, by the liquid processing unit U1 and the heat treatment unit U2, a developing processing for the resist film after being subjected to the exposure processing as well as a heat treatment required to perform the developing processing. The liquid processing unit U1 is configured to perform a liquid processing (developing processing) using a developing liquid on the workpiece W. The liquid processing unit U1 is configured to perform the developing processing on the resist film formed on the front surface Wa of the workpiece W by supplying a developing liquid onto the front surface Wa of the workpiece W after being subjected to the exposure processing. After performing the developing processing by the developing liquid, the liquid processing unit U1 washes away the developing liquid on the front surface Wa of the workpiece W with a rinse liquid. The heat treatment unit U2 is configured to perform various kinds of heat treatments required to perform the developing processing. As a specific example, these heat treatments may include a heat treatment before development (PEB: Post Exposure Bake) and a heat treatment after development (PB: Post Bake).

Within the processing block 5, a shelf unit U10 is provided near the carrier block 4. The shelf unit U10 is partitioned into a multiple number of cells arranged in a vertical direction. A transfer device A7 including an elevating arm is provided near the shelf unit U10. The transfer device A7 is configured to move the workpiece W up and down between the cells of the shelf unit U10.

Within the processing block 5, a shelf unit U11 is provided near the interface block 6. The shelf unit U11 is partitioned into a multiple number of cells arranged in the vertical direction.

The interface block 6 is configured to deliver the workpiece W to/from the exposure apparatus 3. For example, the interface block 6 incorporates therein a transfer device A8 including a delivery arm, and is connected to the exposure apparatus 3. The transfer device A8 passes the workpiece W placed on the shelf unit U11 to the exposure device 3. The transfer device A8 receives the workpiece W from the exposure apparatus 3 and returns it back into the shelf unit U11.

The above-described coating and developing apparatus 2 is an example of the substrate processing apparatus, and the configuration of the substrate processing apparatus is not particularly limited as long as it includes a film processing unit configured to perform a preset processing including the formation of the resist film on the front surface of the workpiece W, and a carry-in/out unit configured to carry the workpiece W to/from the film processing unit. In the coating and developing apparatus 2 described above, the processing block 5 and the interface block 6 function as the film processing unit that performs the preset processing including the formation of the resist film on the front surface Wa. The carrier block 4 functions as the carry-in/out unit serving to carry the workpiece W to/from the film processing unit. The preset processing performed by the processing block 5 and the interface block 6 may or may not include the development of the exposed resist film.

The control device 100 controls the coating and developing apparatus 2 partially or in overall. The control device 100 is composed of one or more control computers. When the control device 100 is composed of a plurality of control computers, these control computers may be interconnected so that communication therebetween is possible.

The control device 100 has, as functional components, a storage 102 and a controller 104. The storage 102 stores therein a program for operating the various units and the various devices included in the coating and developing apparatus 2. The storage 102 also stores therein various types of data (for example, information based on signals for operating the processing units and the like included in the coating and developing apparatus 2), and information from sensors and the like provided in individual units. The storage 102 is, for example, a semiconductor memory, an optical recording disk, a magnetic recording disk, or a magneto-optical recording disk. The program may also be included in an external storage device separate from the storage 102 or in an intangible medium such as a radio signal. The program may be installed from these other media to the storage 102 to be stored in the storage 102.

The controller 104 controls operations of the various units and the various devices included in the coating and developing apparatus 2 based on the program read out from the storage 102. The controller 104 is configured to perform, at least, a control of the processing block 5 so as to perform the preset processing including the formation of the resist film on the front surface Wa of the workpiece W and the development of the exposed resist film, and a control of the carrier block 4 so as to carry the workpiece W to/from the processing block 5. Hereinafter, various processing units included in the coating and developing apparatus 2 will be described.

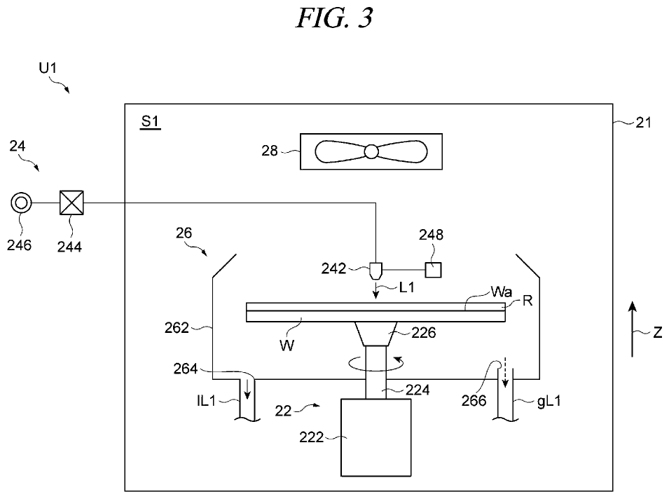

(Liquid processing unit) FIG. 3 schematically illustrates an example of the liquid processing unit U1 of the processing module 12. The liquid processing unit U1 is configured to perform a liquid processing using a processing liquid on the workpiece W. The liquid processing unit U1 includes, by way of example, a housing 21, a rotating/holding unit 22, a processing liquid supply 24, a cover member 26, and a blower 28. The housing 21 accommodates therein the rotating/holding unit 22, a part of the processing liquid supply 24, the cover member 26, and the blower 28. The housing 21 forms a processing space S1 (first processing space) in which the liquid processing using the processing liquid by the liquid processing unit U1 is performed.

The rotating/holding unit 22 is configured to hold and rotate the workpiece W. The rotating/holding unit 22 includes, by way of example, a rotational driving unit 222, a shaft 224, and a holder 226. The rotational driving unit 222 is operated based on a signal from the control device 100 to rotate the shaft 224. The rotational driving unit 22 includes, by way of example, a power source such as an electric motor. The holder 226 is provided on a leading end of the shaft 224.

The workpiece W is placed on the holder 226 with the front surface Wa thereof facing upwards. The holder 226 holds the workpiece W substantially horizontally by, for example, suction. That is, the rotating/holding unit 22 rotates the workpiece W around a central axis (rotation axis), which is perpendicular to the front surface Wa of the workpiece W, while holding the substrate W in a substantially horizontal posture. The holder 226 may hold the workpiece W so that the rotation axis thereof substantially coincides with the center of the workpiece W.

The processing liquid supply 24 is configured to supply a processing liquid for forming the resist film onto the front surface Wa of the workpiece W held by the rotating/holding unit 22 (holder 226). Hereinafter, the processing liquid supplied by the processing liquid supply 24 is referred to as “processing liquid L1,” and the resist film formed on the front surface Wa is referred to as “resist film R.” The processing liquid L1 (another processing liquid) is a resist liquid for forming the resist film R. In the present disclosure, supplying a fluid of a gas or a liquid (for example, the processing liquid L1) to the main surface (for example, the front surface Wa) of the workpiece W includes bringing the fluid into contact with a film already formed on the main surface.

The processing liquid supply 24 includes, for example, a processing liquid source 246, a nozzle 242, an opening/closing valve 244, and a nozzle driving unit 248. The processing liquid source 246 is a liquid source of the processing liquid L1, and it supplies the processing liquid L1 to the nozzle 242. The processing liquid source 246 includes, for example, a tank storing the processing liquid L1 therein, and a pump for force-feeding the processing liquid L1. The nozzle 242 discharges the processing liquid L1 supplied from the processing liquid source 246 toward the front surface Wa of the workpiece W.

The opening/closing valve 244 is configured to open and close a flow path of the processing liquid L1 between the processing liquid source 246 and the nozzle 242 based on a signal from the control device 100. The nozzle driving unit 248 is configured to move the nozzle 242 at least in the direction (horizontal direction) along the front surface Wa of the workpiece W based on a signal from the control device 100.

The cover member 26 is disposed around the rotating/holding unit 22. The cover member 26 includes, by way of example, a cup main body 262, a drain port 264, and an exhaust port 266. The cup main body 262 serves as a liquid receptacle that receives the processing liquid L1 supplied to the workpiece W for the liquid processing on the workpiece W.

The drain port 264 is provided at a bottom of the cup main body 262. Waste of the processing liquid L1 collected by the cup main body 262 is drained to the outside of the liquid processing unit U1 via the drain port 264. A drain line IL1 (first drain line) is connected to the drain port 264. The drain line IL1 drains the processing liquid L1 to the outside of the coating and developing apparatus 2 from the processing space S1 for performing therein the processing with the processing liquid L1 in the liquid processing unit U1. The drain line IL1 is a pipe that guides the processing liquid L1 to the outside of the coating and developing apparatus 2. The drain line IL1 connected to one liquid processing unit U1 may join another drain line IL1 connected to another liquid processing unit U1 in the processing module 12 to drain the processing liquid L1 to the outside of the coating and developing apparatus 2.

The exhaust port 266 is provided at the bottom of the cup main body 262. A gas in the housing 21 is exhausted to the outside of the liquid processing unit U1 through the exhaust port 266. An exhaust line gL1 (first exhaust line) is connected to the exhaust port 266. The exhaust line gL1 exhausts the gas within the processing space S1 (housing 21) for performing therein the processing with the processing liquid L1 in the liquid processing unit U1 to the outside of the coating and developing apparatus 2. The exhaust line gL1 is a pipe that guides the gas exhausted from the inside of the housing 21 to the outside of the coating and developing apparatus 2. The exhaust line gL1 connected to one liquid processing unit U1 may join another exhaust line gL1 connected to another liquid processing unit U1 in the processing module 12 to exhaust the gas within the housing 21 to the outside of the coating and developing apparatus 2.

The blower 28 is disposed above the rotating/holding unit 22 and the cover member 26 in the housing 21. The blower 28 forms a downflow toward the cover member 26 and the rotating/holding unit 22 based on a signal from the control device 100.

After the liquid processing unit U1 forms a coating film of the processing liquid Lion the front surface Wa, the heat treatment unit U2 performs the heat treatment on the workpiece W, so that the resist film R is formed. In FIG. 3, the coating film of the processing liquid L1 before the heat treatment is indicated by “R”. As described above, the liquid processing unit U1 and the heat treatment unit U2 of the processing module 12 perform the processing (first processing) of forming the resist film on the front surface Wa of the workpiece W.

(Inverting unit) As illustrated in FIG. 2, the processing block 5 of the coating and developing apparatus 2 may have one or more inverting units 18. The processing block 5 of the coating and developing apparatus 2 may have a plurality of inverting units 18. The one or more inverting units 18 may be disposed in some of the cells of the shelf unit U10. The one or more inverting units 18 may be disposed in, among the multiple number of cells of the shelf unit U10, those corresponding to the processing module 11.

The inverting unit 18 (inverting device) is configured to invert the rear surface Wb of the workpiece W upside down. The inverting unit 18 turns the workpiece W upside down into a state in which the rear surface Wb faces upwards from a state in which the rear surface Wb faces downwards. Also, the inverting unit 18 inverts the workpiece W upside down from the state in which the rear surface Wb faces upwards into the state in which the rear surface Wb faces down.

<Film on Rear Surface Wb>

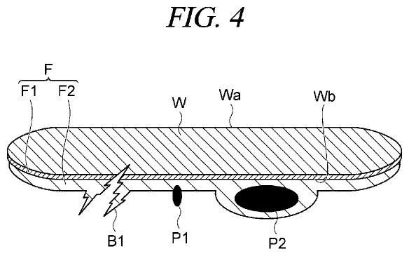

FIG. 4 schematically illustrates an example of a cross section of the workpiece W. A film may be formed on the rear surface Wb (the main surface opposite to the front surface Wa) of the workpiece W for various purposes. Hereinafter, the film formed on the rear surface Wb of the workpiece W is referred to as “film F.” The film F (rear surface film) may be a single-layered film or a multi-layered film. The film F may include a silicon oxide film F1 and a silicon nitride film F2. The silicon oxide film F1 and the silicon nitride film F2 may be stacked in this order on the rear surface Wb of the workpiece W. Another film may exist between the silicon oxide film F1 and the silicon nitride film F2. In FIG. 4, illustration of the film (such as the resist film R) formed on the front surface Wa of the workpiece W is omitted.

The film F may be formed prior to the processing (the formation and the development of the resist film R) in the coating and developing apparatus 2. The film F may be previously formed before being carried into the coating and developing apparatus 2. A foreign substance exists on the film F formed on the rear surface Wb. For example, the foreign substance present on the film F may be generated due to a contact between the rear surface Wb of the workpiece W and another member (for example, a member holding the workpiece W) or due to the processing on the workpiece W, such as the formation of the film. The foreign substance present on the film F includes, by way of example, a particle P1 attached to the rear surface Wb of the workpiece W, a burr B1 formed on the rear surface Wb of the workpiece W, and a particle P2 embedded in the film F.

In the coating and developing apparatus 2 (the processing block 5 and the interface block 6), a processing of removing the foreign substance from the rear surface Wb of the workpiece W is performed, so that a defect on the rear surface Wb is reduced. The coating and developing apparatus 2 has, for example, one or more first rear surface processing units 30 and one or more second rear surface processing units 40 (see FIG. 2).

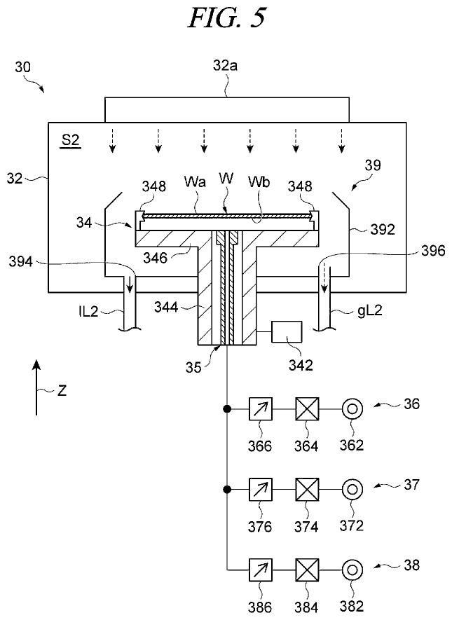

(First rear surface processing unit) FIG. 5 schematically illustrates an example of the first rear surface processing unit 30. The first rear surface processing unit 30 may be provided in the processing module 11. The first rear surface processing unit 30 (film removing unit) is configured to perform a processing (second processing) of supplying a processing liquid to the film F formed on the rear surface Wb of the workpiece W opposite to the front surface Wa to remove the film F. The processing liquid supplied by the first rear surface processing unit 30 is referred to as “processing liquid L2.” The processing liquid L2 is a chemical liquid capable of removing at least a part of the film F. The first rear surface processing unit 30 is configured to etch the film F with the processing liquid L2, which is the chemical liquid capable of removing the film F.

The first rear surface processing unit 30 may supply the processing liquid L2 for the etching to the rear surface Wb in the state that the workpiece W is held with the rear surface Wb thereof facing downwards (that is, the processing liquid L2 may be supplied from below). The first rear surface processing unit 30 has, for example, a housing 32, a rotating/holding unit 34, a processing liquid supply 35, and a cover member 39.

The housing 32 accommodates therein a part of the rotating/holding unit 34, a part of the processing liquid supply 35, and the cover member 39. The housing 32 forms a processing space S2 (second processing space) in which the processing using the processing liquid by the first rear surface processing unit 30 is performed. A blower 32a is provided at a ceiling portion of the housing 32, and this blower 32a forms a downflow in the housing 32. The blower 32a may be a FFU (Fun Filter Unit).

The rotating/holding unit 34 is configured to hold and rotate the workpiece W. The rotating/holding unit 34 may hold a peripheral portion (periphery and the vicinity thereof) of the workpiece Win the state that the rear surface Wb of the workpiece W faces downwards. The rotating/holding unit 34 includes, for example, a rotational driving unit 342, a shaft 344, a holder 346, and a plurality of grippers 348. The rotational driving unit 342 is operated based on a signal from the control device 100 to rotate the shaft 344. The rotational driving unit 342 includes a power source such as, but not limited to, an electric motor. The holder 346 is provided on a leading end of the shaft 344.

The plurality of grippers 348 are provided on a top surface of the holder 346. The plurality of grippers 348 grip the peripheral portion of the workpiece W. The grippers 348 may grip (hold) the peripheral portion of the workpiece W in the state that a gap is provided between the top surface of the holder 346 and the workpiece W. The grippers 348 hold the workpiece W, allowing the rear surface Wb of the workpiece W to face downwards. The rotating/holding unit 34 rotates the workpiece W around a center axis (rotation axis), which is perpendicular to the front surface Wa of the workpiece W, while holding the workpiece W in a substantially horizontal posture. The plurality of grippers 348 may grip the peripheral portion of the workpiece W so that the rotation axis substantially coincides with the center of the workpiece W.

The processing liquid supply 35 is configured to supply the processing liquid L2 (one or more processing liquids) to the rear surface Wb of the workpiece W held by the plurality of grippers 348. The processing liquid supply 35 may supply the processing liquid L2 to the rear surface Wb of the workpiece W from below. An insertion hole is formed through central portions of the shaft 344 and the holder 346 along the rotation axis, and the processing liquid supply 35 is disposed in this insertion hole. The processing liquid supply 35 includes a flow path extending along the rotation axis to guide the processing liquid L2. An upper end of the processing liquid supply 35 discharges the processing liquid L2 to the rear surface Wb of the workpiece W held by the plurality of grippers 348.

Connected to the processing liquid supply 35 are, for example, a first chemical liquid supply 36, a second chemical liquid supply 37, and a rinse liquid supply 38. A liquid is supplied to the processing liquid supply 35 from any one of the first chemical liquid supply 36, the second chemical liquid supply 37, and the rinse liquid supply 38. The processing liquid supply 35 supplies the received liquid to the rear surface Wb of the workpiece W. The processing liquid supply 35 discharges the processing liquid L2 supplied from either one of the first chemical liquid supply 36 and the second chemical liquid supply 37 to the rear surface Wb. The first rear surface processing unit 30 may have a heater configured to heat the processing liquid L2 discharged from the processing liquid supply to a predetermined temperature range.

The first chemical liquid supply 36 is configured to supply a first chemical liquid as the processing liquid L2 to the processing liquid supply 35. The first chemical liquid is a processing liquid configured to remove the film F. The first chemical liquid supply 36 includes a first chemical liquid source 362, an opening/closing valve 364, and a flow rate controller 366. The first chemical liquid source 362, the opening/closing valve 364, and the flow rate controller 366 are arranged in a flow path of the first chemical liquid in this order from the upstream side.

The first chemical liquid source 362 is a liquid source of the first chemical liquid, and includes, by way of example, a tank storing the first chemical liquid therein. The opening/closing valve 364 opens or closes the flow path of the first chemical liquid between the first chemical liquid source 362 and the processing liquid supply 35 based on a signal from the control device 100. The flow rate controller 366 adjusts the flow rate of the first chemical liquid supplied from the first chemical liquid source 362 to the processing liquid supply 35 based on a signal from the control device 100. The first chemical liquid may be hydrofluoric acid.

The second chemical liquid supply 37 is configured to supply a second chemical liquid as the processing liquid L2 to the processing liquid supply 35. The second chemical liquid is a processing liquid configured to remove the film F. The second chemical liquid supply 37 includes a second chemical liquid source 372, an opening/closing valve 374, and a flow rate controller 376. The second chemical liquid source 372, the opening/closing valve 374, and the flow rate controller 376 are disposed in a flow path of the second chemical liquid in this order from the upstream side.

The second chemical liquid source 372 is a liquid source of the second chemical liquid, and includes, for example, a tank storing the second chemical liquid therein. The opening/closing valve 374 opens or closes the flow path of the second chemical liquid between the second chemical liquid source 372 and the processing liquid supply 35 based on a signal from the control device 100. The flow rate controller 376 adjusts the flow rate of the second chemical liquid supplied from the second chemical liquid source 372 to the processing liquid supply 35 based on a signal from the control device 100. The second chemical liquid may be SC-1 which is a mixed solution of ammonia, hydrogen peroxide and water. In the present disclosure, the processing liquid L2 is a generic term for the first chemical liquid and the second chemical liquid configured to remove the film F. That is, the processing liquid L2 means either one of the first chemical liquid and the second chemical liquid, or both of the first chemical liquid and the second chemical liquid.

The rinse liquid supply 38 is configured to supply a rinse liquid to the processing liquid supply 35. The rinse liquid is a liquid configured to rinse away the chemical liquid supplied to the rear surface Wb of the workpiece W, and may be DIW (Deionized Water). The rinse liquid supply 38 includes a rinse liquid source 382, an opening/closing valve 384, and a flow rate controller 386. The rinse liquid source 382, the opening/closing valve 384, and the flow rate controller 386 are arranged in a flow path of the rinse liquid in this order from the upstream side.

The rinse liquid source 382 is a liquid source of the rinse liquid, and includes, for example, a tank storing therein the rinse liquid. The opening/closing valve 384 opens or closes the flow path of the rinse liquid between the rinse liquid source 382 and the processing liquid supply 35 based on a signal from the control device 100. The flow rate controller 386 adjusts the flow rate of the rinse liquid supplied from the rinse liquid source 382 to the processing liquid supply 35 based on a signal from the control device 100.

The cover member 39 is disposed around the rotating/holding unit 34. The cover member 39 includes, by way of example, a cup main body 392, a drain port 394, and an exhaust port 396. The cup main body 392 serves as a liquid receptacle that receives the processing liquid L2 such as the first chemical liquid supplied to the rear surface Wb of the workpiece W.

The drain port 394 is provided at a bottom of the cup main body 392. Waste of the processing liquid L2 collected by the cup main body 392 is drained to the outside of the first rear surface processing unit 30 via the drain port 394. A drain line IL2 (second drain line) is connected to the drain port 394. The drain line IL2 drains the processing liquid L2 (the processing liquid L2 and the rinse liquid) to the outside of the coating and developing apparatus 2 from the processing space S2 in which the processing with the processing liquid L2 in the first rear surface processing unit 30 is performed.

The drain line IL2 is a pipe that guides the processing liquid L2 (the processing liquid L2 and the rinse liquid) to the outside of the coating and developing apparatus 2. The drain line IL2 connected to one first rear surface processing unit 30 may join another drain line IL2 connected to another first rear surface processing unit 30 to drain the processing liquid L2 to the outside of the coating and developing apparatus 2. The drain line IL2 drains the processing liquid L2 to the outside of the coating and developing apparatus 2 independently of the above-described drain line IL1 connected to the liquid processing unit U1 (see FIG. 2). In this case, the drain line IL2 guides the processing liquid L2 to the outside of the coating and developing apparatus 2 without joining the drain line ILL

The exhaust port 396 is provided at the bottom of the cup main body 392. A gas in the housing 32 is exhausted to the outside of the first rear surface processing unit 30 through the exhaust port 396. An exhaust line gL2 (second exhaust line) is connected to the exhaust port 396. The exhaust line gL2 exhausts the gas in the processing space S2 (in the housing 32), in which the processing with the processing liquid L2 in the first rear surface processing unit 30 is performed, to the outside of the coating and developing apparatus 2.

The exhaust line gL2 is a pipe that guides the gas exhausted from the housing 32 to the outside of the coating and developing apparatus 2. The exhaust line gL2 connected to one first rear surface processing unit 30 may join another exhaust line gL2 connected to another first rear surface processing unit 30 to exhaust the gas within the housing 32 to the outside of the coating and developing apparatus 2. The exhaust line gL2 exhausts the gas within the housing 32 to the outside of the coating and developing apparatus 2 independently of the above-described exhaust line gL1 connected to the liquid processing unit U1 (see FIG. 2). In this case, the exhaust line gL2 guides the gas within the housing 32 to the outside of the coating and developing apparatus 2 without joining the exhaust line gL1.

The first rear surface processing unit 30 configured as described above first holds the peripheral portion of the workpiece W with the front surface Wa facing upwards (with the rear surface Wb facing downwards) by the plurality of grippers 348. Then, the first rear surface processing unit 30 rotates the workpiece W held by the grippers 348 by the rotational driving unit 342. Thereafter, the first rear surface processing unit 30 sequentially supplies the multiple chemical liquids toward the central region of the rear surface Wb of the workpiece W being rotated from the processing liquid supply 35. As an example, the first rear surface processing unit 30 supplies the hydrofluoric acid, the DIW, the SC-1, and the DIW in this order from the processing liquid supply 35 toward the central region of the rear surface Wb of the workpiece W being rotated.

As a result of supplying the multiple chemical liquids toward the central region of the rear surface Wb of the workpiece W from the processing liquid supply 35, the film F formed on the rear surface Wb is etched. As the film F is etched, the particle P1 attached to the rear surface Wb and the particle P2 embedded in the film F of the rear surface Wb may be removed. After performing a rinsing processing of washing away the SC-1 remaining on the rear surface Wb with the DIW as the rinse liquid, the first rear surface processing unit 30 then performs a processing of drying the workpiece W by rotating the workpiece W in the state that no chemical liquid is supplied thereto.

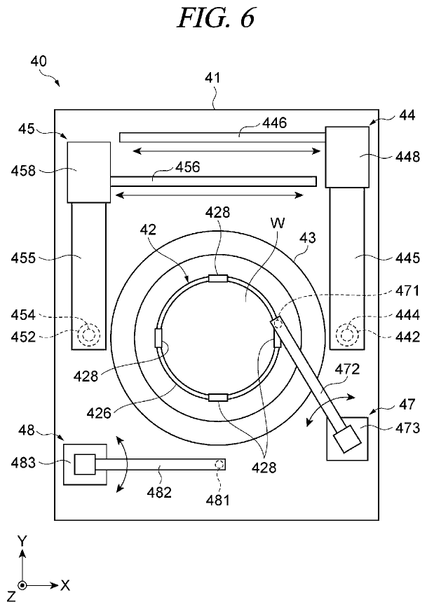

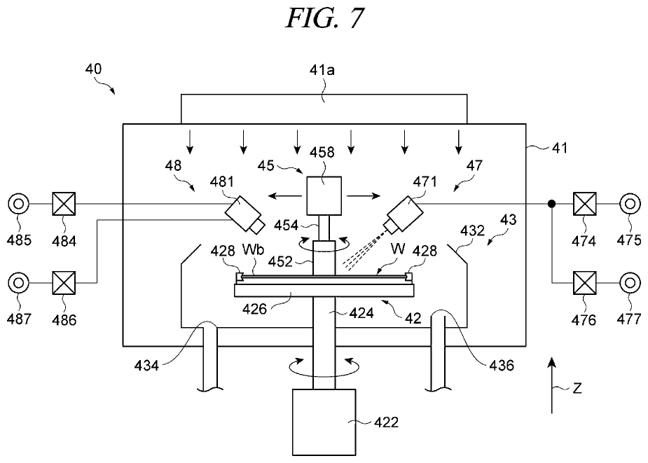

(Second rear surface processing unit) FIG. 6 and FIG. 7 schematically illustrate an example of the second rear surface processing unit 40. The second rear surface processing unit 40 (foreign substance removing unit) is configured to perform a processing (third processing) of moving a brush along the rear surface Wb of the workpiece W processed by the first rear surface processing unit 30 in the state that the brush is brought into contact with the rear surface Wb of the workpiece W. By moving the brush along the rear surface Wb while keeping the brush in contact with the rear surface Wb, the foreign substance present on the rear surface Wb can be removed. Bringing a member such as the brush into contact with the rear surface Wb includes bringing the member into contact with a film such as the film F already formed on the rear surface Wb.

The second rear surface processing unit 40 may perform a processing of removing the foreign substance on the rear surface Wb by using two or more (two or more types of) brushes. When the two or more brushes (two or more types of brushes) are used, the second rear surface processing unit 40 brings the brushes into contact with the rear surface Wb and moves them along the rear surface Wb at different timings. The second rear surface processing unit 40 performs the processing on the workpiece W after being inverted by the inverting unit 18 (that is, the workpiece W with the rear surface Wb facing upwards). The second rear surface processing unit 40 may perform the processing of removing the foreign substance on the rear surface Wb of the workpiece W while holding the workpiece W so that the rear surface Wb thereof faces upwards. The following description will be provided for an example where the second rear surface processing unit removes the foreign substance by using two brushes (two types of brushes).

The second rear surface processing unit 40 may perform a polishing processing on the rear surface Wb of the workpiece W, and, after the polishing processing, may perform a cleaning processing on the rear surface Wb to remove the foreign substance on the rear surface Wb. In the polishing processing, the second rear surface processing unit 40 polishes the rear surface Wb by moving a polishing brush along the rear surface Wb while keeping the polishing brush in contact with the rear surface Wb. In the cleaning processing, the second rear surface processing unit 40 cleans the rear surface Wb by moving a cleaning brush along the rear surface Wb while keeping the cleaning brush in contact with the rear surface Wb.

The second rear surface processing unit 40 includes, for example, a housing 41, a rotating/holding unit 42, a cover member 43, a polishing unit 44, a cleaning unit 45, a first supply 47, and a second supply 48. The housing 41 accommodates therein a part of the rotating/holding unit 42, the cover member 43, the polishing unit 44, the cleaning unit a part of the first supply 47, and a part of the second supply 48. The housing 41 forms a processing space in which the processing by the second rear surface processing unit 40 is performed. A blower 41a is provided at a ceiling portion of the housing 41, and the blower 41a forms a downflow in the housing 41. The blower 41a may be a FFU.

The rotating/holding unit 42 is configured to hold and rotate the workpiece W. The rotating/holding unit 42 may hold the peripheral portion of the workpiece W in the state that the rear surface Wb of the workpiece W faces upwards. The rotating/holding unit 42 includes, for example, a rotational driving unit 422, a shaft 424, a main body 426, and a plurality of grippers 428. The rotational driving unit 422 is operated based on a signal from the control device 100 and rotates the shaft 424. The rotational driving unit 422 includes a power source such as, but not limited to, an electric motor. The main body 426 is provided on a leading end of the shaft 424. The main body 426 is a member formed in a disk shape, and the diameter of the main body 426 is larger than the diameter of the workpiece W.

The plurality of grippers 428 are provided on a top surface of the main body 426. The plurality of grippers 428 grip the peripheral portion of the workpiece W. The plurality of grippers 428 may grip (hold) the peripheral portion of the workpiece W in the state that a gap is provided between the top surface of the main body 426 and the workpiece W. The plurality of grippers 428 may grip (hold) the peripheral portion of the workpiece W, allowing the rear surface Wb of the workpiece W to face upwards. The rotating/holding unit 42 rotates the workpiece W around a central axis (rotation axis), which is perpendicular to the front surface Wa of the workpiece W, while holding the workpiece W in a substantially horizontal posture. The plurality of grippers 428 may grip the peripheral portion of the workpiece W so that the rotation axis thereof substantially coincides with the center of the workpiece W.

The cover member 43 is provided around the rotating/holding unit 42. The cover member 43 includes, for example, a cup main body 432, a drain port 434, and an exhaust port 436. The cup main body 432 serves as a liquid receptacle that receives a chemical liquid or the like supplied to the rear surface Wb of the workpiece W. The drain port 434 is provided at a bottom of the cup main body 432. The chemical liquid collected by the cup main body 432 is drained to the outside of the second rear surface processing unit 40 (the coating and developing apparatus 2) via the drain port 434. The exhaust port 436 is provided at the bottom of the cup main body 432. A gas in the housing 41 is exhausted to the outside of the second rear surface processing unit 40 (the coating and developing apparatus 2) through the exhaust port 436.

The polishing unit 44 is configured to polish the rear surface Wb of the workpiece W held by the plurality of grippers 428. The polishing unit 44 includes, by way of example, a polishing brush 442 (brush for polishing), a shaft 444, an arm 445, a rail 446, and a driving unit 448. The polishing brush 442 may also include a whetstone. The polishing brush 442 may include a diamond whetstone or a diamond sheet. The polishing brush 442 may be formed in a cylindrical shape. The polishing brush 442 polishes the rear surface Wb of the workpiece W as it is moved along the rear surface Wb in the state that a leading end thereof is in contact with the rear surface Wb.

The polishing brush 442 is connected to the arm 445 via the shaft 444 extending along the Z-axis direction. The arm 445 is formed so as to extend in a horizontal direction, and supports the polishing brush 442 with the shaft 444 therebetween. The driving unit 448 includes a power source such as an electric motor, and moves the arm 445 along the rail 446. The driving unit 448 is also capable of moving the arm 445 in the Z-axis direction. The polishing unit 44 may have a rotational driving unit configured to rotate the polishing brush 442 around an axis passing through the polishing brush 442. The polishing unit 44 may rotate the polishing brush 442 with respect to the shaft 444 by the rotational driving unit.

The cleaning unit 45 is configured to clean the rear surface Wb of the workpiece W held by the plurality of grippers 428 after the polishing by the polishing unit 44. The cleaning unit 45 includes, for example, a cleaning brush 452 (brush for cleaning), a shaft 454, an arm 455, a rail 456, and a driving unit 458. The cleaning brush 452 may be made of PVC sponge, urethane sponge or nylon fiber. The cleaning brush 452 may be formed in a cylindrical shape. The cleaning brush 452 cleans the rear surface Wb of the workpiece W as it is moved along the rear surface Wb in the state that a leading end thereof is in contact with the rear surface Wb.

The cleaning brush 452 is connected to the arm 455 via the shaft 454 extending along the Z-axis direction. The arm 455 is formed so as to extend in a horizontal direction, and supports the cleaning brush 452 with the shaft 454 therebetween. The driving unit 458 includes a power source such as an electric motor, and moves the arm 455 along the rail 456. The driving unit 458 is also capable of moving the arm 455 in the Z-axis direction. The cleaning unit 45 may have a rotational driving unit configured to rotate the cleaning brush 452 around an axis passing through the cleaning brush 452. The cleaning unit 45 may rotate the cleaning brush 452 with respect to the shaft 454 by the rotational driving unit.

The first supply 47 is configured to supply the cleaning liquid and the rinse liquid separately to the workpiece W held by the plurality of grippers 428. The first supply 47 is disposed outside the cover member 43. The first supply 47 includes, by way of example, a nozzle 471, an arm 472, a driving unit 473, an opening/closing valve 474, a first cleaning liquid source 475, an opening/closing valve 476, and a rinse liquid source 477.

The nozzle 471 is configured to discharge the cleaning liquid to the workpiece W, and discharge the rinse liquid to the workpiece W. The arm 472 supports the nozzle 471. The driving unit 473 includes a power source such as an electric motor, and serves to rotate the arm 472 around an axis along the Z-axis direction and move the arm 472 up and down.

The nozzle 471 is connected to the first cleaning liquid source 475 via the opening/closing valve 474 or the like. The opening/closing valve 474 opens or closes a flow path between the nozzle 471 and the first cleaning liquid source 475 based on a signal from the control device 100. When the opening/closing valve 474 is opened, the nozzle 471 discharges a first cleaning liquid supplied from the first cleaning liquid source 475 to the rear surface Wb of the workpiece W. The first cleaning liquid supplied from the first cleaning liquid source 475 is, for example, SC-1.

The nozzle 471 is also connected to the rinse liquid source 477 via the opening/closing valve 476 or the like. The opening/closing valve 476 opens or closes a flow path between the nozzle 471 and the rinse liquid source 477 based on a signal from the control device 100. When the opening/closing valve 476 is opened, the nozzle 471 discharges the rinse liquid supplied from the rinse liquid source 477 to the rear surface Wb of the workpiece W. The rinse liquid supplied from the rinse liquid source 477 is, for example, DIW.

The second supply 48 is configured to supply a misted cleaning liquid, which is obtained by mixing a cleaning liquid and a gas, to the workpiece W held by the plurality of grippers 428. The second supply 48 is disposed outside the cover member 43. The second supply 48 includes, for example, a nozzle 481, an arm 482, a driving unit 483, an opening/closing valve 484, a second cleaning liquid source 485, an opening/closing valve 486, and a gas source 487.

The nozzle 481 is, for example, a dual-fluid nozzle, and discharges the misted cleaning liquid to the workpiece W. The arm 482 supports the nozzle 481. The driving unit 483 includes a power source such as an electric motor, and serves to rotate the arm 482 around an axis along the Z-axis direction and move the arm 482 up and down.

The nozzle 481 is connected to the second cleaning liquid source 485 via the opening/closing valve 484 or the like, and is connected to the gas source 487 via the opening/closing valve 486 or the like. The opening/closing valve 484 opens or closes a flow path between the nozzle 481 and the second cleaning liquid source 485 based on a signal from the control device 100. The opening/closing valve 486 opens or closes a flow path between the nozzle 481 and the gas source 487 based on a signal from the control device 100.

The second supply 48 mixes a second cleaning liquid supplied from the second cleaning liquid source 485 with the gas supplied from the gas source 487 within the nozzle 481, and discharges the misted cleaning liquid, which is obtained as a result of the mixing, to the rear surface Wb of the workpiece W from the nozzle 481. The second cleaning liquid supplied from the second cleaning liquid source 485 is, for example, DIW, and the gas supplied from the gas source 487 is, for example, an inert gas such as, but not limited to, a nitrogen gas.

The second rear surface processing unit 40 configured as described above may perform the processing on the workpiece W in the state that the rear surface Wb is inverted by the inverting unit 18 to face upwards. First of all, the second rear surface processing unit 40 holds the peripheral portion of the workpiece W with the plurality of grippers 428 in the state that the rear surface Wb faces upwards. Then, the second rear surface processing unit 40 rotates the workpiece W held by the plurality of grippers 428 by the rotational driving unit 422. While rotating the workpiece W, the second rear surface processing unit 40 brings the polishing brush 442 into contact with the rear surface Wb of the workpiece W from above by the driving unit 448 of the polishing unit 44. Thereafter, while rotating the polishing brush 442 with respect to the shaft 444, the second rear surface processing unit 40 moves the polishing brush 442 along a diametrical direction of the workpiece W by the driving unit 448, while maintaining the state in which the polishing brush 442 is in contact with the rear surface Wb. As a result, the rear surface Wb of the workpiece W is polished (the polishing processing is performed on the rear surface Wb), so that the burr B1 remaining on the rear surface Wb of the workpiece W can be removed.

After performing the polishing processing on the rear surface Wb, the second rear surface processing unit 40 brings the cleaning brush 452 into contact with the rear surface Wb of the workpiece W from above by the driving unit 458 of the cleaning unit 45, while supplying the first cleaning liquid from the first supply 47 to the rear surface Wb of the workpiece W being rotated. Then, while rotating the cleaning brush 452 with respect to the shaft 454, the second rear surface processing unit 40 moves the cleaning brush 452 along the diametrical direction of the workpiece W by the driving unit 458, while maintaining the state in which the cleaning brush 452 is in contact with the rear surface Wb. As a result, the rear surface Wb of the workpiece W is cleaned (the cleaning processing is performed on the rear surface Wb), so that debris of the burr B1 remaining on the rear surface Wb after the polishing processing can be removed.

After the cleaning processing for the rear surface Wb, the second rear surface processing unit 40 locates, by the driving unit 483 of the second supply 48, the nozzle 481 above the rear surface Wb of the workpiece W being rotated, and supplies the misted second cleaning liquid to the rear surface Wb of the workpiece W from the nozzle 481. As a result, the rear surface Wb of the workpiece W is further cleaned, so that the foreign substance not removed by the etching processing in the first rear surface processing unit 30, the polishing processing by the polishing brush 442, and the cleaning processing by the cleaning brush 452 can be removed from the rear surface Wb.

After the cleaning by the misted second cleaning liquid from the second supply 48, the second rear surface processing unit 40 supplies the rinse liquid from the first supply 47 to the rear surface Wb of the workpiece W. As a result, the chemical liquid remaining on the rear surface Wb of the workpiece W is washed away (the rinsing processing is performed on the rear surface Wb). Then, the second rear surface processing unit 40 performs a processing (drying processing) of drying the workpiece W by rotating the workpiece W in the stat that no chemical liquid or the like is supplied to the workpiece W.

Upon the completion of all the processings by the second rear surface processing unit 40, the inverting unit 18 (second inverting device) inverts the workpiece W after being processed by the second rear surface processing unit 40 upside down. This inverting unit 18 that inverts the workpiece W upside down such that the rear surface Wb faces downward after the processing by the second rear surface processing unit 40 may be the same unit as or different from the inverting unit 18 that inverts the workpiece W upside down before the processing by the second rear surface processing unit 40. The inverting unit 18 configured to invert the workpiece W upside down before the processing by the second rear surface processing unit 40 may invert the workpiece W after being subjected to the processing by the first rear surface processing unit 30 from the state where the rear surface Wb faces down into the state where the rear surface Wb faces upwards.

[Substrate Processing Method]

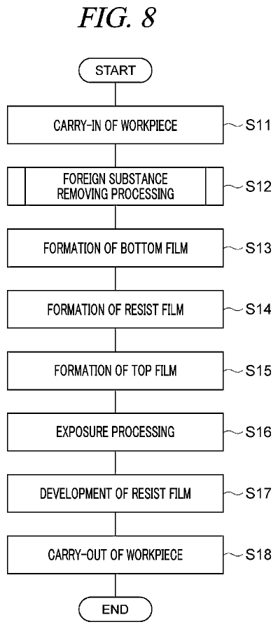

Now, a coating and developing processing performed in the coating and developing apparatus 2 will be described as an example of a substrate processing method. FIG. 8 is a flowchart illustrating an example of a series of processes performed by the control device 100 for a single sheet of workpiece W. First, the control device 100 performs a process S11. For example, in the process S11, the controller 104 of the control device 100 controls the transfer device A1 to carry the workpiece W within the carrier C to the shelf unit U10, and controls the transfer device A7 to place the workpiece W in the cell for the processing module 11 in the shelf unit U10. Through the process S11, the workpiece W is carried into the processing block 5 and the interface block 6.

Next, the control device 100 performs a process S12. For example, in the process S12, the controller 104 controls the inverting unit 18, the first rear surface processing unit 30 and the second rear surface processing unit 40 so as to perform a processing (hereinafter, referred

to as “foreign substance removing processing”) of removing the foreign substance from the rear surface Wb of the workpiece W. Details of the foreign substance removing processing in the process S12 will be described later.

Thereafter, the control device 100 performs a process S13. For example, in the process S13, the controller 104 controls the transfer device A3 to transfer the workpiece W of the shelf unit U10 (inverting unit 18) to the liquid processing unit U1 and the heat treatment unit U2 in the processing module 11. Further, the controller 104 controls the liquid processing unit U1 and the heat treatment unit U2 to form the bottom film on the front surface Wa of the workpiece W. Thereafter, the control device 100 controls the transfer device A3 to return the workpiece W having the bottom film formed thereon to the shelf unit U10, and controls the control device A7 to place this workpiece W in the cell for the processing module 12.

Subsequently, the control device 100 performs a process S14. For example, in the process S14, the controller 104 controls the transfer device A3 to transfer the workpiece W of the shelf unit U10 to the liquid processing unit U1 and the heat treatment unit U2 in the processing module 12. Further, the controller 104 controls the liquid processing unit U1 and the heat treatment unit U2 to form the resist film R on the front surface Wa of the workpiece W. Then, the controller 104 controls the transfer device A3 to return the workpiece W to the shelf unit U10, and controls the transfer device A7 to place this workpiece W in the cell for the processing module 13.

Afterwards, the control device 100 performs a process S15. For example, in the process S15, the controller 104 controls the transfer device A3 to transfer the workpiece W of the shelf unit U10 to each unit in the processing module 13. Further, the controller 104 controls the liquid processing unit U1 and the heat treatment unit U2 to form the top film on the resist film R of the workpiece W. Then, the controller 104 controls the transfer device A3 to transfer the workpiece W to the shelf unit U11.

Thereafter, a process S16 is performed. Before the process S16, the controller 104 controls the transfer device A8 to send the workpiece W of the shelf unit U11 to the exposure apparatus 3. In the process S16, the exposure processing is performed on the workpiece W by the exposure apparatus 3. Upon the completion of the process S16, the controller 104 controls the transfer device A8 to receive the workpiece W after being subjected to the exposure processing from the exposure apparatus 3 and place it in the cell for the processing module 14 in the shelf unit U11.

Next, the control device 100 performs a process S17. For example, in the process S17, the controller 104 controls the transfer device A3 to transfer the workpiece W of the shelf unit U11 to each unit in the processing module 14. Further, the controller 104 controls the liquid processing unit U1 and the heat treatment unit U2 to perform the developing processing for the resist film R of the workpiece W and the heat treatment required for the developing processing, respectively. As the developing processing for the resist film R is performed, the resist pattern is formed on the front surface Wa of the workpiece W.

Subsequently, the control device 100 performs a process S18. For example, in the process S18, the controller 104 controls the transfer device A3 to return the workpiece W to the shelf unit U10, and controls the transfer device A7 and the transfer device A1 to return this workpiece W back into the carrier C. Through the process S18, the workpiece W is carried out from the processing block 5 and the interface block 6.

Through the above-described processes, the coating and developing processing for the single sheet of workpiece W is completed. The control device 100 causes the coating and developing apparatus 2 to perform the coating and developing processing for each of a plurality of subsequent workpieces W in the same way as in the processing of the processes S11 to S18 described above.

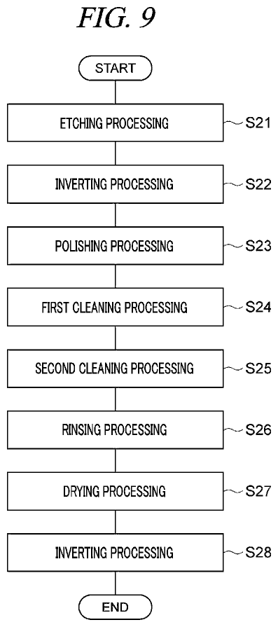

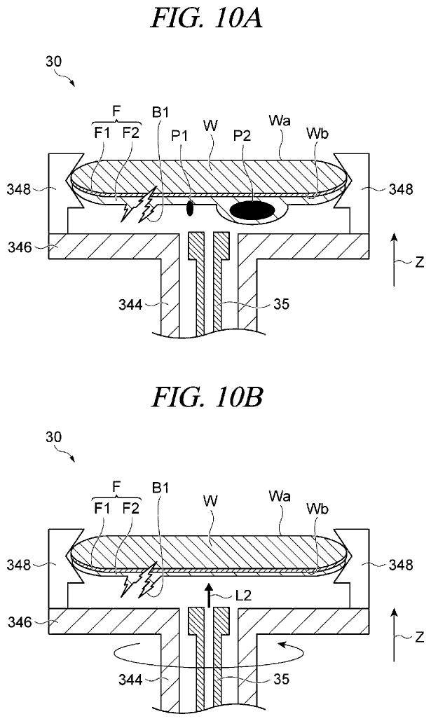

FIG. 9 is a flowchart showing an example of the foreign substance removing processing of the process S12. In the process S12, the control device 100 first performs a process S21. For example, in the process S21, the controller 104 controls the first rear surface processing unit 30 and the like so that the workpiece W is held by the plurality of grippers 348 of the rotating/holding unit 34, as shown in FIG. 10A. In this stage, the particle P1, the particle P2, and the burr B1 exist as the foreign substances on the rear surface Wb on which the film F is formed, for example. After the workpiece W is held by the plurality of grippers 348, the controller 104 controls the first rear surface processing unit 30 to perform the etching processing on the rear surface Wb of the workpiece W.

In the etching processing, the controller 104 rotates the workpiece W held by the plurality of grippers 348 by the rotational driving unit 342, as shown in FIG. 1013. While rotating the workpiece W, the controller 104 supplies the first chemical liquid (for example, hydrofluoric acid) toward the rear surface Wb of the workpiece W being rotated from the processing liquid supply 35. The hydrofluoric acid supplied from the processing liquid supply 35 may have a concentration ranging from 45% to 55% and a temperature ranging from 20° C. to 50° C. A supply time of the hydrofluoric acid may be in the range of seconds to 180 seconds.

Thereafter, by the processing liquid supply 35, the controller 104 supplies the second chemical liquid (for example, SC-1) toward the rear surface Wb of the workpiece W being rotated. The SC-1 has a mixing ratio of ammonia:hydrogen peroxide:water=1:1:5 to 1:10:100, and has a temperature ranging from 20° C. to 70° C. A supply time of the SC-1 may be 10 seconds to 30 seconds. After the supply of the second chemical liquid, the controller 104 supplies, by the processing liquid supply 35, the rinse liquid (for example, DIW) toward the rear surface Wb of the workpiece W being rotated. After the supply of the rinse liquid, the controller 104 increases the rotation number of the workpiece W and carries on the rotation of the workpiece W by the rotational driving unit 342 for a predetermined period of time, so that the chemical liquid remaining on the rear surface Wb of the workpiece W is removed to the outside of the workpiece W, and then, the workpiece W is dried.

The controller 104 may perform the process S21 so that a part of the film F remains after the etching processing. In this case, it is possible to suppress the rear surface Wb of the workpiece W from being damaged in another processing (for example, polishing processing) performed after the etching processing. In the process S21, as the plurality of chemical liquids are sequentially supplied to the rear surface Wb of the workpiece W, the film F is etched. By using the plurality of chemical liquids, the silicon nitride film F2 as the surface layer of the film F can be selectively etched.

Next, the control device 100 performs a process S22. For example, in the process S22, the controller 104 controls the transfer device A3 to transfer the workpiece W from the first rear surface processing unit 30 to the inverting unit 18. Then, the controller 104 inverts the workpiece W upside down by the inverting unit 18 so that the rear surface Wb faces upwards (that is, the front surface Wa faces downwards).

Subsequently, the control device 100 performs a process S23. For example, in the process S23, the controller 104 controls the transfer device A3 to transfer the workpiece W with the rear surface Wb thereof facing upwards from the inverting unit 18 to the second rear surface processing unit 40. The controller 104 controls the transfer device A3 to carry the workpiece W into the housing 41 of the second rear surface processing unit 40, while keeping the rear surface Wb face up (that is, the front surface Wa faces down).

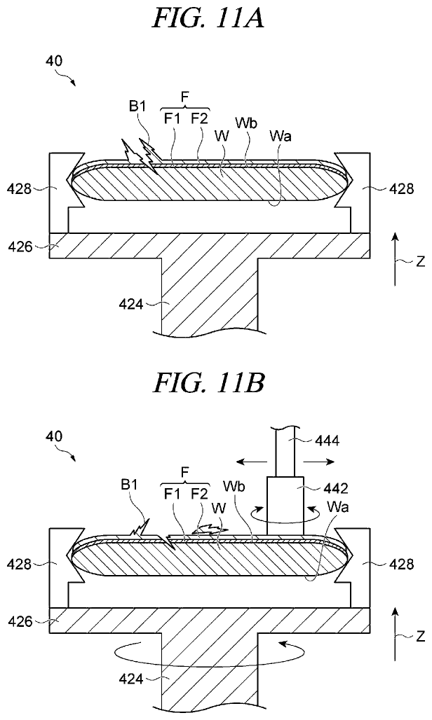

When the workpiece W is carried in, the controller 104 controls the second rear surface processing unit 40 and the like so that the workpiece W is held by the plurality of grippers 428 of the rotating/holding unit 42, as illustrated in FIG. 11A. In this stage, the burr B1 as the foreign substance remains on the rear surface Wb of the workpiece W. The controller 104 controls the second rear surface processing unit 40 to perform the polishing processing on the rear surface Wb of the workpiece W in the state that the rear surface Wb faces upwards.

In the polishing processing, the controller 104 rotates, by the rotational driving unit 422, the workpiece W held by the plurality of grippers 428, as shown in FIG. 11B. While rotating the workpiece W, the controller 104 brings, by the driving unit 448 of the polishing unit 44, the leading end of the polishing brush 442 into contact with the rear surface Wb of the workpiece W from above. While rotating the polishing brush 442, the controller 104 moves the polishing brush 442 in the diametrical direction of the workpiece W (for example, from the center of the workpiece W toward the outside of the edge of the workpiece W) by the driving unit 448. In the process S23, as the polishing brush 442 is moved (relative to the rear surface Wb) along the rear surface Wb in the state that the polishing brush 442 is in contact with the rear surface Wb, the rear surface Wb of the workpiece W is polished, and as a result, the burr B1 is removed. In this stage, the debris of the burr B1 remain on the rear surface Wb as the foreign substances.

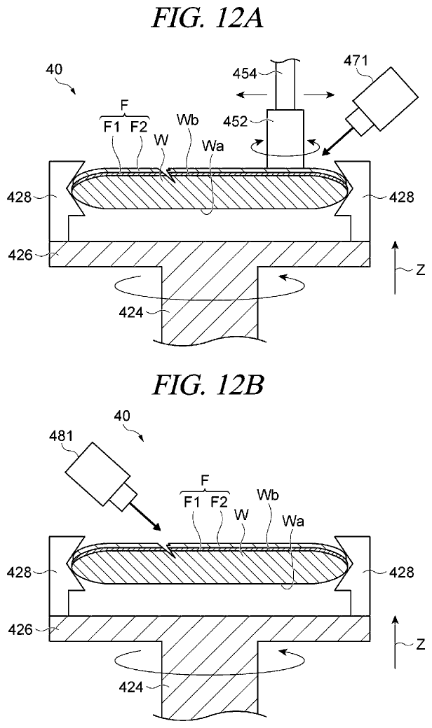

Next, the control device 100 performs a process S24. For example, in the process S24, the controller 104 controls the second rear surface processing unit 40 to perform a first cleaning processing on the rear surface Wb. In the first cleaning processing, while rotating the workpiece W by the rotational driving unit 422, the controller 104 brings the leading end of the cleaning brush 452 into contact with the rear surface Wb of the workpiece W from above by the driving unit 458 of the cleaning unit 45, as illustrated in FIG. 12A. Then, while rotating the cleaning brush 452, the controller 104 moves the cleaning brush 452 in the diametrical direction of the workpiece W (for example, from the center of the workpiece W toward the outside of the edge thereof) by the driving unit 458.

While moving the cleaning brush 452, the controller 104 controls the first supply 47 to supply the first cleaning liquid (for example, SC-1) toward the rear surface Wb from the nozzle 471 disposed above the workpiece W being rotated. The SC-1 discharged from the nozzle 471 has the mixing ratio of ammonia:hydrogen peroxide:water=1:1:5 to 1:10:100, and has the temperature ranging from 20° C. to 70° C. In the process S24, as the cleaning brush 452 is moved along the rear surface Wb (relative to the rear surface Wb) in the state that it is in contact with the rear surface Wb, the rear surface Wb of the workpiece W is cleaned. As a result, the debris of the burr B1 remaining on the rear surface Wb are removed.

Next, the control device 100 performs a process S25. For example, in the process S25, the controller 104 controls the second rear surface processing unit 40 to perform a second cleaning processing on the rear surface Wb. In the second cleaning processing, as shown in FIG. 12B, the second supply 48 is controlled to supply the misted second cleaning liquid toward the rear surface Wb from the nozzle 481 disposed above the workpiece W being rotated. By supplying the misted second cleaning liquid, the rear surface Wb of the workpiece W is cleaned, and the foreign substance not removed by the etching processing, the polishing processing, and the first cleaning processing may be removed from the rear surface Wb.

Subsequently, the controller 104 performs a process S26. For example, in the process S26, the controller 104 controls the second rear surface processing unit 40 to perform a rinsing processing on the rear surface Wb. In the rinsing processing, the controller 104 controls the first supply 47 to supply the rinse liquid toward the rear surface Wb from the nozzle 471 disposed above the workpiece W being rotated. Through this rinsing processing, the chemical liquid remaining on the rear surface Wb of the workpiece W is washed away.

Thereafter, the controller 104 performs a process S27. For example, in the process S27, the controller 104 controls the second rear surface processing unit 40 to perform a drying processing on the workpiece W. In the drying processing, the controller 104 increases the rotation number of the workpiece W by the rotational driving unit 422, and carries on the rotation of the workpiece W for a predetermined period of time. Through this drying processing, the rinse liquid remaining on the rear surface Wb of the workpiece W is removed to the outside of the workpiece W, so that the workpiece W is dried.

Afterwards, the control device 100 performs a process S28. For example, in the process S28, the controller 104 controls the transfer device A3 to transfer the workpiece W from the second rear surface processing unit 40 to the inverting unit 18. The controller 104 controls the inverting unit 18 to invert the workpiece W upside down so that the rear surface Wb faces downwards (so that the front surface Wa faces upwards). Through the above-described processes, the foreign substance removing processing of the process S12 is completed.

In the series of processes shown in FIG. 8 and FIG. 9, the first rear surface processing unit 30 and the second rear surface processing unit 40 perform the processings on the rear surface Wb before the resist film R is formed. Specifically, the first rear surface processing unit 30 and the second rear surface processing unit 40 perform the processings on the rear surface Wb before the resist film R is formed on the front surface Wa by the processing module 12 and after the workpiece W is carried into the processing block 5. In the above-described series of processes, no other processing using a processing liquid is performed on the workpiece W after the etching processing is performed by the first rear surface processing unit 30, and the second rear surface processing unit 40 performs the polishing processing and the first cleaning processing.

### Second Exemplary Embodiment

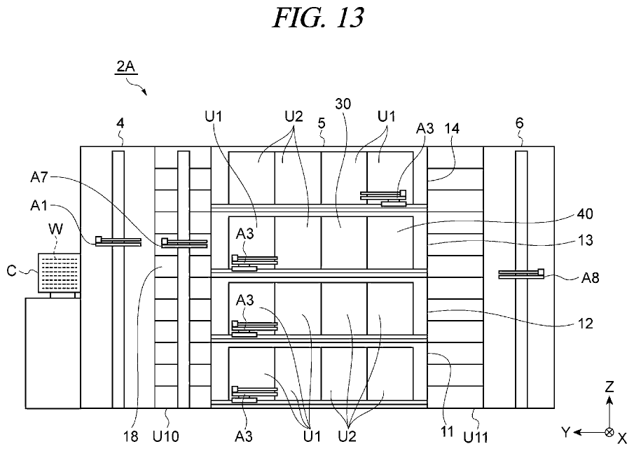

FIG. 13 schematically illustrates a coating and developing apparatus 2A belonging to the substrate processing system 1 according to a second exemplary embodiment. The coating and developing apparatus 2A is different from the coating and developing apparatus 2 in that the processing module 13, instead of the processing module 11, is equipped with the first rear surface processing unit 30 and the second rear surface processing unit 40. In the coating and developing apparatus 2A, one or more inverting units 18 may be disposed, among the multiple number of cells of the shelf unit U10, in the cell corresponding to the processing module 13. One or more inverting units 18 may be disposed in the cell of the shelf unit U11.

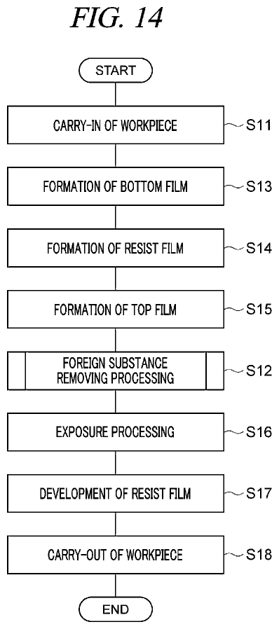

FIG. 14 is a flowchart illustrating a series of processes performed by the control device 100 in the substrate processing system 1 equipped with the coating and developing apparatus 2A. In the series of the processes shown in FIG. 14, the processing sequence of the foreign substance removing processing of the process S12 is different, as compared to the series of processes shown in FIG. 8. The controller 104 of the control device 100 may perform the process S12 prior to the exposure processing of the process S16 after the formation of the top film in the process S15.

In the series of processes shown in FIG. 14, the first rear surface processing unit 30 and the second rear surface processing unit 40 provided in the processing module 13 perform the processings on the rear surface Wb before the exposure processing is performed on the workpiece W after the resist film R is formed on the front surface Wa by the processing module 12. In the series of processes shown in FIG. 14, after the film formation is performed on the front surface Wa, the controller 104 performs the process S12 without performing another processing using a processing liquid on the workpiece W.

### Third Exemplary Embodiment

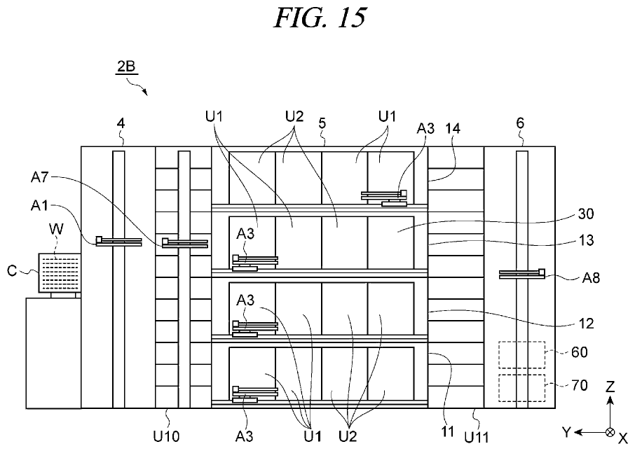

FIG. 15 schematically illustrates a coating and developing apparatus 2B belonging to the substrate processing system 1 according to a third exemplary embodiment. The coating and developing apparatus 2B is different from the coating and developing apparatus 2A in that it is equipped with a polishing unit 60 and a cleaning unit 70 instead of the second rear surface processing unit 40. In the coating and developing apparatus 2B, each of the polishing unit 60 and the cleaning unit 70 or the polishing unit 60 and the cleaning unit 70 together may serve as the foreign substance removing unit configured to move the brush along the rear surface Wb of the workpiece W while keeping the brush in contact with the rear surface Wb. The polishing unit 60 and the cleaning unit 70 may be disposed in the interface block 6.

The polishing unit 60 is configured to polish the rear surface Wb of the workpiece W by moving the polishing brush along the rear surface Wb in the state that the polishing brush is in contact with the rear surface Wb. The polishing unit 60 performs a processing (polishing processing) of removing the foreign substance from the rear surface Wb in the state that the workpiece W is held with the rear surface Wb thereof facing downwards. The polishing unit 60 performs the polishing processing on the workpiece W after being subjected to the processing by the first rear surface processing unit 30 disposed in the processing module 13. Between the processing by the first rear surface processing unit 30 and the processing by the polishing unit 60, the workpiece W is not inverted upside down by the inverting unit 18. Between the processing by the first rear surface processing unit 30 and the processing by the polishing unit 60, no other processing using a processing liquid may be performed on the workpiece W.

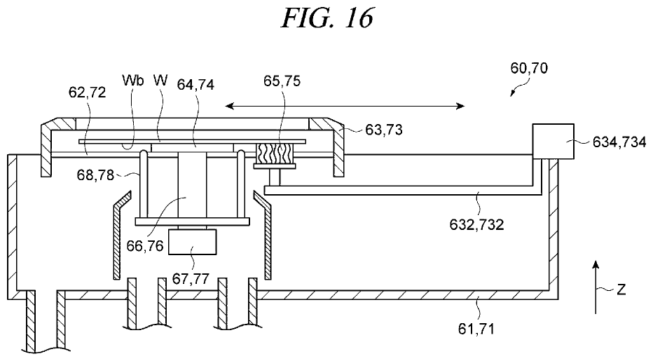

FIG. 16 schematically illustrates an example of the polishing unit 60. The polishing unit 60 includes, for example, a housing 61, two attraction pads 62, a frame body 63, a holder 64, a shaft 66, a driving unit 67, elevating pins 68, and a polishing brush 65.

The housing 61 is formed so as to have an open top. The two attraction pads 62 are disposed with the holder 64 therebetween so as to hold the peripheral region of the rear surface Wb of the workpiece W, when viewed from the top. Each of the two attraction pads 62 is formed so as to extend in one horizontal direction. The frame body 63 supports both ends of each of the two attraction pads 62. The frame body 63 is movable along a horizontal direction and an up-and-down direction by a driving unit. The workpiece W can be transferred between the two attraction pads 62 and the holder 64.

The holder 64 is configured to hold the workpiece W in a horizontal state with the rear surface Wb thereof facing downwards. The holder 64 may hold the central region of the rear surface Wb of the workpiece W by attraction. The holder 64 is connected to the driving unit 67 via the shaft 66. The holder 64 can be rotated and moved up and down by the driving unit 67. The elevating pins 68 are disposed around the holder 64 (shaft 66), and can be moved up and down by an elevational driving unit.

The polishing brush 65 (brush for polishing) is supported by a support 632. The support 632 is connected to a driving unit 634. The driving unit 634 is disposed in the housing 61, and is configured to move the support 632 along a direction perpendicular to the paper plane of FIG. 16. The polishing brush 65 may be configured to be rotated around an axis passing through the polishing brush 65 by a driving unit provided in the support 632.

The polishing unit 60 polishes the rear surface Wb by moving, by the driving unit 634, the polishing brush 65 along the rear surface Wb of the workpiece W in the state that the top surface of the polishing brush 65 is in contact with the rear surface Wb. The polishing unit 60 polishes the central region of the rear surface Wb with the polishing brush 65 in the state that the workpiece W is held by the two attraction pads 62. The polishing unit 60 polishes the peripheral region of the rear surface Wb with the polishing brush 65 in the state that the workpiece W is held by the holder 64.

FIG. 16 schematically illustrates an example of the cleaning unit 70. The cleaning unit 70 is configured to clean the rear surface Wb of the workpiece W by moving the cleaning brush along the rear surface Wb in the state that the cleaning brush is in contact with the rear surface Wb. The cleaning unit 70 performs a processing (cleaning processing) of removing the foreign substance from the rear surface Wb in the state that the workpiece W is held with the rear surface Wb thereof facing downwards. The cleaning unit 70 performs the cleaning processing on the workpiece W after being subjected to the processing by the polishing unit 60. Between the processing by the polishing unit 60 and the processing by the cleaning unit 70, no other processing using a processing liquid is performed on the workpiece W.

The cleaning unit 70 may have the same configuration as the polishing unit 60. The cleaning unit 70 includes, by way of example, a housing 71, two attraction pads 72, a frame body 73, a holder 74, a shaft 76, a driving unit 77, elevating pins 79, and a cleaning brush 75. The individual members of the cleaning unit 70 may have the same configurations and functions as corresponding members of the polishing unit 60, except that the cleaning brush 75 is made of a material for cleaning (for example, plastic fiber), unlike the polishing brush 65.

The cleaning brush 75 (brush for cleaning) is supported by a support 732. The support 732 is connected to a driving unit 734. The support 732 and the driving unit 734 have the same configurations and functions as the support body 632 and the driving unit 634, respectively. The cleaning unit 70 cleans the rear surface Wb of the workpiece W by moving, by the driving unit 734, the cleaning brush 75 along the rear surface Wb while keeping the top surface of the cleaning brush 75 in contact with the rear surface Wb. The cleaning unit 70 cleans the central region of the rear surface Wb with the cleaning brush 75 in the state that the workpiece W is held by the two attraction pads 72. The cleaning unit 70 cleans the peripheral region of the rear surface Wb with the cleaning brush in the state that the workpiece W is held by the holder 74.

In the substrate processing system 1 equipped with the coating and developing apparatus 2B, the control device 100 may perform the series of processes shown in FIG. 14. In this case, the polishing unit 60 performs the polishing processing in the process S12, and the cleaning unit 70 performs the cleaning processing in the process S12. Instead of the polishing unit 60 and the cleaning unit 70, the coating and developing apparatus 2B may be equipped with a single rear surface processing unit (foreign substance removing unit) configured to perform a polishing processing with a polishing brush, and, after the polishing processing, perform a cleaning processing with a cleaning brush.

### MODIFICATION EXAMPLES

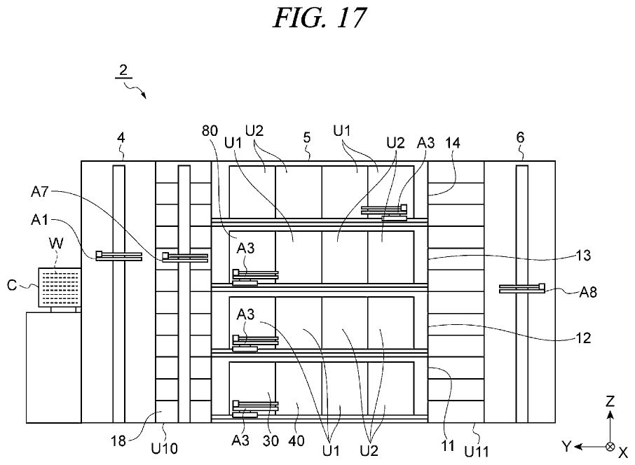

The coating and developing apparatus 2 (2A, 2B) may perform a processing of forming a friction reducing film on the rear surface Wb of the workpiece W in addition to the foreign substance removing processing. The friction reducing film is a film configured to reduce friction between a portion holding the rear surface Wb of the workpiece W and the rear surface Wb of the workpiece W during the exposure processing in the exposure apparatus 3. The following description will be provided for an example where the coating and developing apparatus 2 according to the first exemplary embodiment performs the processing of forming the friction reducing film. As shown in FIG. 17, the coating and developing apparatus 2 may include a friction reducing film forming unit 80 (friction reducing film forming device). The film processing unit composed of the processing block 5 and the interface block 6 may have the friction reducing film forming unit 80. The friction reducing film forming unit 80 is disposed in the processing module 13, for example.

The friction reducing film forming unit 80 forms the friction reducing film on the rear surface Wb of the workpiece W by, for example, depositing a gas (hereinafter referred to as “source gas”) containing a material for forming the friction reducing film on the rear surface Wb. With the front surface Wa facing upwards, the workpiece W may be bent so that the peripheral portion of the workpiece W is bent downwards as compared to the central portion thereof. If the workpiece W including such a bending is attracted to and held by a holding portion (a holding surface of a stage) that holds the workpiece W during the exposure processing in the exposure apparatus 3, there is a risk that an excessive stress may be applied to the peripheral portion of the workpiece W held by the stage.

Meanwhile, if the friction reducing film is formed on the rear surface Wb of the workpiece W, the friction reducing film has a high contact angle with respect to the holding portion of the exposure apparatus 3. Thus, as compared to the case where the friction reducing film is not formed, a coefficient of friction between the rear surface Wb and the holding portion of the exposure apparatus 3 is reduced. In this case, the friction reducing film enables the workpiece W to be placed so as to be slid on the holding portion of the exposure apparatus 3, so that the aforementioned stress at the peripheral portion can be reduced. The kind of the friction reducing film is not particularly limited as long as it can reduce the friction. As an example, a fluororesin film may be used. The friction reducing film forming unit 80 may form the friction reducing film on the rear surface Wb of the workpiece W after being subjected to the processing by the second rear surface processing unit 40.

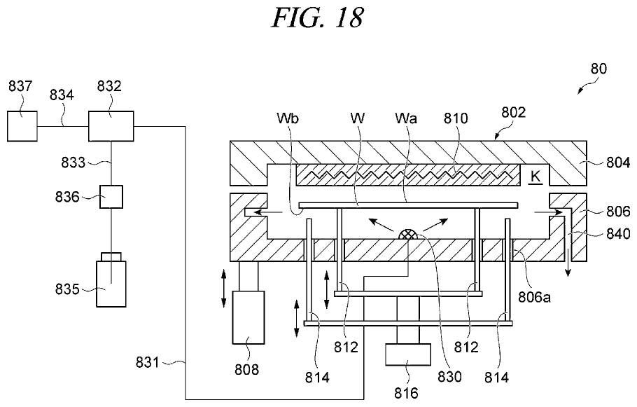

FIG. 18 schematically shows an example of the friction reducing film forming unit 80. In FIG. 18, a cross section of a part of the friction reducing film forming unit 80 is shown. The friction reducing film forming unit 80 includes, by way of example, a chamber 802, an elevational driving unit 808, a heater 810, a support 812, a support 814, an elevational driving unit 816, and a gas supply 830.

The chamber 802 accommodates therein the workpiece W, and forms a processing space K in which the processing of forming the friction reducing film is performed. The chamber 802 includes an upper chamber 804 and a lower chamber 806. The upper chamber 804 may be fixed at a set position. The lower chamber 806 may be configured to be movable up and down, and the elevational driving unit 808 moves the lower chamber 806 up and down. As the lower chamber 806 is raised to come into firm contact with the upper chamber 804, the hermetically sealed processing space K is formed inside the chamber 802. Meanwhile, as the lower chamber 806 is lowered, the inside of the chamber 802 is opened to the atmosphere.

The heater 810 is configured to heat the workpiece W placed in the processing space K. The heater 810 may be provided in the upper chamber 804. Each of the support 812 and the support 814 supports the workpiece W. The support 812 may include three elevating pins, and the support 814 may include three elevating pins. The support 812 and the support 814 are configured to be movable up and down individually, and are moved up and down by the elevational driving unit 816. The lower chamber 806 is provided with through holes 806a through which the elevating pins belonging to the supports 812 and 814 are inserted.

The gas supply 830 is configured to supply the source gas to the rear surface Wb of the workpiece W supported by the support 812 or the support 814. The gas supply 830 is provided at a central portion of an internal bottom surface of the chamber 802. The gas supply 830 may be configured to discharge the source gas to the entire rear surface Wb of the workpiece W.

A gas supply line 831 through which the source gas flows is connected to the gas supply 830. The gas supply line 831 is connected to a vaporizer 832 configured to vaporize a source liquid in a liquid state into the source gas. The vaporizer 832 is connected to a liquid supply line 833 through which the source liquid flows and a gas supply line 834 through which a nitrogen gas flows. The liquid supply line 833 is connected to a source tank 835 that stores therein the source liquid. The liquid supply line 833 is provided with a pump 836 configured to force-feed the source liquid from the source tank 835 to the vaporizer 832. The gas supply line 834 is connected to a nitrogen gas source 837 that supplies the nitrogen gas to the vaporizer 832.

A heater is provided within the vaporizer 832 to heat and vaporize the source liquid introduced from the source tank 835. When the source gas is a fluororesin, for example Teflon (registered trademark) resin, a heating temperature in the vaporizer 832 is, for example, 180° C. The source gas vaporized in the vaporizer 832 is force-fed by the nitrogen gas supplied from the nitrogen gas source 837 to be supplied to the gas supply 830.

An exhaust path 840 through which a gas is exhausted from the inside of the chamber 300 (processing space K) is provided inside a sidewall of the lower chamber 806. The exhaust path 840 is connected to an exhaust line. The exhaust line is connected to an exhaust device such as, but not limited to, a vacuum pump, and serves to exhaust the gas from the processing space K to the outside of the coating and developing apparatus 2. In addition, the configuration of the friction reducing film forming unit 80 is not particularly limited as long as it can form the friction reducing film on the rear surface Wb of the workpiece W.

The coating and developing apparatus 2 may be equipped with an ultraviolet radiation unit configured to radiate ultraviolet rays to the rear surface Wb of the workpiece W. The ultraviolet radiation unit may activate the rear surface Wb by radiating the ultraviolet rays to the rear surface Wb before the friction reducing film is formed on the rear surface Wb in the friction reducing film forming unit 80. After the exposure processing, the ultraviolet radiation unit may remove the friction reducing film by radiating the ultraviolet rays to the friction reducing film formed on the rear surface Wb of the workpiece W.

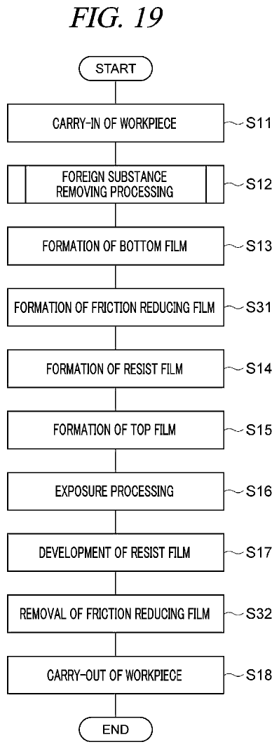

FIG. 19 is a flowchart showing a series of processes performed by the control device 100 in the case where the coating and developing apparatus 2 includes the friction reducing film forming unit 80 and the ultraviolet radiation unit. The series of processes shown in FIG. 19 is different from the series of processes shown in FIG. 8 in that processes S31 and S32 are further performed. The control device 100 may perform the process S31 after the bottom film is formed in the process S13 and before the resist film R is formed in the process S14.

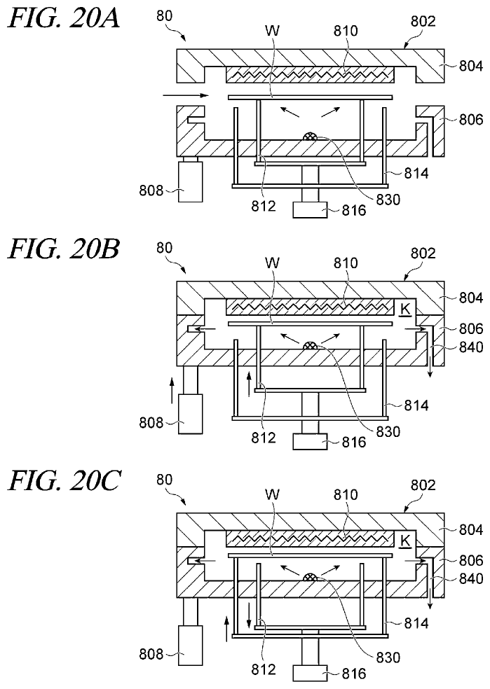

For example, in the process S31, the controller 104 of the control device 100 controls the friction reducing film forming unit 80 to form the friction reducing film on the entire rear surface Wb of the workpiece W after being subjected to the foreign substance removing processing in the process S12. For example, the controller 104 controls the friction reducing film forming unit 80 and the like to carry the workpiece W into the chamber 802 in the state that the lower chamber 806 is lowered by the elevational driving unit 808, as illustrated in FIG. 20A. When the workpiece W is carried into the chamber 802, the rear surface Wb of the workpiece W is supported by the support 812.

Then, as shown in FIG. 20B, the controller 104 raises the lower chamber 806 by the elevational driving unit 808, thus forming the sealed processing space K inside the chamber 802. Further, the controller 104 raises the support 812 by the elevational driving unit 816, thus allowing the workpiece W to be placed at a predetermined processing position. Thereafter, the controller 104 controls the friction reducing film forming unit 80 and the like to supply the source gas to the rear surface Wb of the workpiece W from the gas supply 830 while heating the workpiece W to a preset temperature (e.g., about 120° C.) by the heater 810. As a result, the source gas is deposited on the rear surface Wb of the workpiece W except for the portions supported by the support 812, so that the friction reducing film is formed. The heating by the heater 810 is performed to accelerate the reaction between the rear surface Wb and the source gas.

After the friction reducing film is formed on the rear surface Wb except for the portions supported by the support 812, the controller 104 raises the support 814 by the elevational driving unit 816 to allow the workpiece W to be supported by the support 814, and, also, lowers the support 812 by the elevational driving unit 816, as shown in FIG. 20C. Then, the controller 104 controls the friction reducing film forming unit 80 and the like to supply the source gas from the gas supply 830 to the rear surface Wb of the workpiece W. As a result, the source gas is deposited on the portions supported by the support 812 as well, and the friction reducing film is formed on the entire rear surface Wb of the workpiece W. While the source gas is being supplied from the gas supply 830, the evacuation of the processing space K is performed through the exhaust path 840, so that the source gas is suppressed from flowing to the front surface Wa of the workpiece W.

The control device 100 may perform the process S32 after the resist film R is developed in the process S17 and before the workpiece W is carried out in the process S18. In the process S32, for example, the controller 104 controls the ultraviolet radiation unit to radiate the ultraviolet rays to the rear surface Wb to remove (peel) the friction reducing film formed on the rear surface Wb.

In the above-described example, the process S31 is performed between the process S13 and the process S14. However, the process S31 may be performed at any timing within a period between the process S12 and the process S16. For example, the process S31 may be performed after the formation of the top film in the process S15 and before the exposure processing in the process S16. In this case, after the friction reducing film is formed in the process S31, no other processing using a processing liquid need to be performed before the exposure processing.

When forming the friction reducing film in the friction reducing film forming unit 80, there is a risk that a small amount of the source gas may be flown to the front surface Wa of the workpiece W. By forming the friction reducing film immediately before the exposure processing after all the films supposed to be formed on the front surface Wa are formed, influence on the film formation that might be caused by the flow of the source gas to the front surface Wa can be avoided. Meanwhile, by forming the friction reducing film on the rear surface Wb before forming the resist film R, influence on the resist film R that might be caused by the heating during the formation of the friction reducing film can be avoided. The timing at which the friction reducing film is formed may be decided in consideration of the kind (material) of the films to be formed on the front surface Wa, various manufacturing conditions, and so forth.

The friction reducing film forming unit 80 may form the friction reducing film on the rear surface Wb of the workpiece W before the processing by the first rear surface processing unit 30 is performed. In this case, the friction reducing film forming unit 80 may form the friction reducing film on the entire rear surface Wb. Even if the friction reducing film is formed on the entire rear surface Wb, the friction reducing film can be removed except for the peripheral portion of the rear surface Wb in the etching processing in the first rear surface processing unit 30 because the peripheral portion of the workpiece W is held. Even if the friction reducing film remains only at the peripheral portion of the rear surface Wb, the stress applied to the peripheral portion of the workpiece W can be reduced by the friction reducing film during the exposure processing.

The friction reducing film forming unit 80 may form the friction reducing film only at the peripheral portion of the rear surface Wb instead of the entire rear surface Wb thereof. For example, the gas supply 830 of the friction reducing film forming unit 80 may be configured to discharge the source gas only to the peripheral portion of the rear surface Wb, or discharge the source gas to the peripheral portion of the rear surface Wb selectively. The range of the peripheral portion (the width of the annular portion) where the friction reducing film is formed may be about 1/15 or about 1/30 of the radius of the workpiece W. For example, when the radius of the workpiece W is 150 mm, the width of the annular portion constituting the peripheral portion where the friction reducing film is formed is about 10 mm or about 5 mm along the diametrical direction.

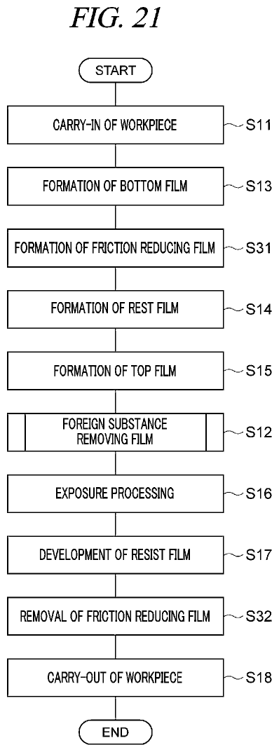

Specifically, the coating and developing apparatus 2A according to the second exemplary embodiment may include the friction reducing film forming unit 80 and the ultraviolet radiation unit. FIG. 21 is a flowchart showing a series of processes performed by the control device 100 in the case where the coating and developing apparatus 2A includes the friction reducing film forming unit 80 and the ultraviolet radiation unit. The series of processes shown in FIG. 21 are different from the series of processes shown in FIG. 14 in that the processes S31 and S32 are further performed. The control device 100 may perform the process S31 after the bottom film is formed in the process S13 and before the resist film R is formed in the process S14.

In the series of processes shown in FIG. 21, the process S31 is performed before the foreign substance removing processing of the process S12. The process S31 may be performed at any timing after the process S11 is performed and before the process S12 is performed. In the foreign substance removing processing of the process S12, the first rear surface processing unit 30 performs the processing of removing the film F from a region of the rear surface Wb of the workpiece W other than the peripheral portion thereof, and the second rear surface processing unit 40 performs the polishing processing and the cleaning processing on the region of the rear surface Wb of the workpiece W other than the peripheral portion.

The coating and developing apparatus 2B according to the third exemplary embodiment may include the friction reducing film forming unit 80 and the ultraviolet radiation unit. The friction reducing film forming unit 80 may be disposed outside the coating and developing apparatus 2. In this case, the friction reducing film may already be formed on the rear surface Wb of the workpiece W before the workpiece W is introduced into the coating and developing apparatus 2 (processing block 5 and interface block 6).

The contents of the present disclosure are not limited to the above-described first to third exemplary embodiments. Some of the matters described in any one of those exemplary embodiments may be applied to another embodiment. The series of processes in each of FIG. 8, FIG. 9, FIG. 14, FIG. 19 and FIG. 21 are just examples and may be modified appropriately. In the series of processes, the controller 104 of the control device 100 may perform one process and the next process in parallel, or may perform the individual processes in an order different from that in the above-described examples. The controller 104 may omit any one of the processes, or may perform a processing different from that described above in any one of the processes.

The foreign substance removing unit of the coating and developing apparatus 2 (2A, 2B) may perform a cleaning processing, not the polishing processing, as the processing of removing the foreign substance from the rear surface Wb. The coating and developing apparatus 2 (2A) include, instead of the second rear surface processing unit 40, a rear surface processing unit (foreign substance removing unit) that is not equipped with the polishing brush and configured to perform the cleaning processing with the cleaning brush. The coating and developing apparatus 2B may not be equipped with the polishing unit 60 but be equipped with the cleaning unit 70 (foreign substance removing unit). The foreign substance removing unit of the coating and developing apparatus 2 (2A, 2B) may perform a polishing processing, not the cleaning processing, as the processing of removing the foreign substance from the rear surface Wb.

The first rear surface processing unit 30 may supply the processing liquid L2 to the rear surface Wb while holding the workpiece W with the rear surface Wb thereof facing upwards. The first rear surface processing unit 30 and the second rear surface processing unit 40 may be configured to perform the processings for the rear surface Wb after the bottom film is formed on the front surface Wa and before the resist film R is formed on the front surface Wa. The first rear surface processing unit 30 and the second rear surface processing unit 40 may be configured to perform the processings for the rear surface Wb after the resist film R is formed on the front surface Wa and before the top film is formed on the front surface Wa.

The way to form the resist film R is not limited to the method of forming it by supplying the processing liquid L1. The film processing unit of the coating and developing apparatus 2 may be equipped with a resist film forming unit configured to form the resist film R by vapor deposition (for example, chemical vapor deposition (CVD)). In one example among the various examples described above, at least a part of the matters described in other examples may be combined.

[Evaluation Results Regarding Foreign Substance Removing Processing]

The flatness of the rear surface Wb affects the exposure processing or the exposure apparatus. Multiple types of foreign substances are contained in the rear surface Wb, and among these foreign substances, it is observed that the height (degree of protrusion from the surroundings) of the foreign substance embedded in the film F, such as the particle P2, is larger than the heights of the other types of foreign substances. Thus, it is found out that that the foreign substance embedded in the film F (hereinafter, referred to as “embedded foreign substance”) greatly affects the flatness of the rear surface Wb. Changes in the height of the embedded foreign substance when performing the etching processing using the processing liquid L2 and at least one of the polishing processing and the cleaning processing (cleaning processing using the brush) as in the above-described exemplary embodiments are investigated.

In the measurement of the height of the embedded foreign substance (the position of the measurement point of the rear surface Wb in the direction perpendicular to the workpiece W), embedded foreign substances are extracted by observing the peripheral region of the rear surface Wb, and an average value of the heights of the extracted foreign substances is calculated. A rate of decrease in the height (=a measurement value of the height after the processing/a measurement value of the height before the processing) of the embedded foreign substance before and after the rear surface Wb is processed is investigated. The processing of removing the foreign substance is performed under the conditions of Comparative Examples 1 and 2 and Experimental Examples 1 to 3. Evaluation results are presented as shown in Table 1.

TABLE 1

| | | | | Rate of |
|---|---|---|---|---|
| | | | | decrease |
| | Etching | Polishing | Cleaning | in height |
| Comparative Example 1 | — | Present | Present | 0.96 |
| Comparative Example 2 | Present(T) | — | — | 0.82 |
| Experimental Example 1 | Present | Present | Present | 0.72 |
| | (T/2) | | | |
| Experimental Example 2 | Present(T) | — | Present | 0.62 |
| Experimental Example 3 | Present(T) | Present | Present | 0.34 |

In Comparative Examples 1 and 2 and Experimental Examples 1 to 3, the rear surface Wb is processed under the following conditions. In Comparative Example 1, the polishing processing and the cleaning processing are performed without performing the etching processing. In Comparative Example 2, the etching processing is performed for a set time T, and neither the polishing processing nor the cleaning processing is performed. The set time T is set to such an extent that substantially the whole of the silicon nitride film F2 in the film F can be removed. In Experimental Example 1, the etching processing is performed for half the set time T, and both the polishing processing and the cleaning processing are performed. In Experimental Example 2, the etching processing is performed for the set time T, and only the cleaning processing is performed without performing the polishing processing. In Experimental Example 3, the etching processing is performed for the set time T, and both the polishing processing and the cleaning processing are performed.

As can be seen from the evaluation results shown in Table 1, the rates of decrease in the height of the embedded foreign substance in Experimental Examples 1 to 3 are larger than those in Comparative Examples 1 and 2. That is, it is found out that the flatness of the rear surface Wb is further improved by the processing on the rear surface Wb in Experimental Examples 1 to 3, as compared to the processing on the rear surface Wb in Comparative Examples 1 and 2. Further, from the comparison of Experimental Examples 2 and Experimental Example 3, it is found out that the rate of decrease is further increased (that is, the flatness is further improved) by performing both the polishing processing and the cleaning processing after the etching processing.

### Effects of Exemplary Embodiments

The coating and developing apparatus 2 (2A, 2B) described above has a film processing unit configured to perform a preset processing including the formation of the resist film Ron the front surface Wa of the workpiece W; and a carry-in/out unit configured to perform the carry-in/carry-out of the workpiece W into/from the film processing unit. The film processing unit includes a resist film forming unit configured to form the resist film R on the front surface Wa of the workpiece W; a film removing unit configured to supply, to the film F formed on the rear surface Wb opposite to the front surface Wa of the workpiece W, the processing liquid L2 configured to remove the film F; and a foreign substance removing unit configured to move a brush along the rear surface Wb of the workpiece W while keeping the brush in contact with the rear surface Wb of the workpiece W after being processed by the film removing unit.

In the coating and developing apparatus 2 (2A, 2B), at least one of a cleaning processing and a polishing processing using the brush is performed after an etching processing on the film F formed on the rear surface Wb is performed. By the etching processing, a foreign substance adhering to the film F and a foreign substance embedded in the film F can be removed from the rear surface Wb, and by moving the brush in contact with the rear surface Wb, a foreign substance remaining on the rear surface Wb can be removed. Thus, it is possible to appropriately remove the foreign substance from the rear surface Wb on which the film F is formed.

In the coating and developing apparatus 2 (2A, 2B), the brush may be the cleaning brush 452 (75). The foreign substance removing unit may polish the rear surface Wb of the workpiece W by moving the polishing brush 442 (65), which is different from a brush for cleaning, along the rear surface Wb of the workpiece W while keeping the polishing brush 442 (65) in contact with the rear surface Wb of the workpiece W. After polishing the rear surface Wb of the workpiece W, the foreign substance removing unit may clean the rear surface Wb of the workpiece W by moving the cleaning brush 452 (75) along the rear surface Wb of the workpiece W while keeping the cleaning brush 452 (75) in contact with the rear surface Wb of the workpiece W. In this case, through the polishing after the etching processing, a burr formed on the rear surface Wb can be removed, and through the cleaning after the polishing, debris of the burr remaining on the rear surface Wb can be removed from the rear surface Wb. Therefore, it is possible to more appropriately remove the foreign substance from the rear surface Wb on which the film F is formed.

In the coating and developing apparatus 2 (2A,2B), the film removing unit may supply the processing liquid L2 to the rear surface Wb of the workpiece W in the state that the workpiece W is held with the rear surface Wb thereof facing downwards. A processing liquid supplied to the rear surface Wb falls downwards. Thus, by supplying the processing liquid L2 in the state that the rear surface Wb faces downwards, it becomes easy to collect the waste of the processing liquid L2. Therefore, efficient collection of the waste of the processing liquid L2 is enabled.

In the coating and developing apparatus 2 (2A, 2B), the foreign substance removing unit may perform a processing of removing the foreign substance on the rear surface Wb of the workpiece W in the state that the workpiece W is held with the rear surface Wb thereof facing downwards. In the case of forming a resist film on the front surface Wa, a processing of forming the film may be performed, while keeping the front surface Wa face upwards in many cases. In this configuration, since the workpiece W need not be inverted upside down when performing the foreign substance removing processing, processes of the processing can be simplified.

The coating and developing apparatus 2 (2A, 2B) may be further equipped with an inverting unit configured to invert the rear surface Wb of the workpiece W upside down. The foreign substance removing unit may process the workpiece W after being inverted by the inverting unit. The foreign substance removing unit may perform the processing of removing the foreign substance on the rear surface Wb of the workpiece W in a state that the workpiece W is held with the rear surface Wb thereof facing upwards. In an area above the held workpiece W, other members are not disposed, unlike in an area below the held workpiece W. In this configuration, by bringing the brush into contact with the rear surface Wb of the workpiece W from above, the processing of removing the foreign substance can be performed on the rear surface Wb. Accordingly, since interference with other members can be avoided, it is easy to bring the brush into contact with the rear surface Wb, and the configuration of the foreign substance removing unit can be simplified.

In the coating and developing apparatus 2 (2A, 2B), the film removing unit may supply the processing liquid L2 to the rear surface Wb of the workpiece W in a state that the workpiece W is held with the rear surface Wb thereof facing downwards. The inverting unit may invert the rear surface Wb of the workpiece W, which is obtained after being processed by the film removing unit, upside down. A processing liquid supplied to the rear surface Wb falls downwards. Thus, by supplying the processing liquid L2 in the state that the rear surface Wb faces downwards, it becomes easy to collect the waste of the processing liquid L2. Therefore, efficient collection of the waste of the processing liquid L2 is enabled.

The coating and developing apparatus 2 (2A, 2B) may be further equipped with a second inverting unit configured to invert the rear surface Wb of the workpiece W, which is obtained after being processed by the foreign substance removing unit, upside down. In this case, even when the foreign substance removing processing is performed while keeping the rear surface Wb face upwards, another processing can be performed while keeping the front surface Wa face upwards after the foreign substance removing processing. Therefore, it is possible to achieve both appropriate removal of the foreign substance and improvement of the efficiency of substrate processing.

In the coating and developing apparatus 2 (2A, 2B), the film removing unit and the foreign substance removing unit may process the rear surface Wb of the workpiece W after the resist film R is formed on the front surface Wa of the workpiece W by the resist film forming unit and before the workpiece W is subjected to the exposure processing. In this case, since the processing of removing the foreign substance from the rear surface Wb is performed before the exposure processing, it is possible to reduce the influence of the foreign substance of the rear surface Wb on the exposure processing or the exposure apparatus. In addition, due to the processing of forming the resist film R, a foreign substance may adhere to the rear surface Wb. In the above-described configuration, since the foreign substance removing processing on the rear surface Wb is performed after the formation of the resist film R, it is possible to reduce the influence of the foreign substance of the rear surface Wb that might be caused by the formation of the resist film R on the exposure processing and the exposure apparatus.

In the coating and developing apparatus 2 (2A, 2B), the film removing unit and the foreign substance removing unit may process the rear surface Wb of the workpiece W after the workpiece W is carried into the film forming unit and before the resist film R is formed on the front surface Wa of the workpiece W by the resist film forming unit. Since the exposure processing is performed after the formation of the resist film R, the processing of removing the foreign substance from the rear surface Wb is performed prior to the exposure processing. Therefore, it is possible to reduce the influence on the exposure processing or the exposure apparatus that might be caused by the foreign substance on the rear surface Wb. In addition, since the foreign substance removing processing is performed on the rear surface Wb before the formation of the resist film R, it is possible to reduce the influence from the foreign substance of the rear surface Wb in the process of forming the resist film R.

In the coating and developing apparatus 2 (2A, 2B), the resist film forming unit may form the resist film R on the front surface Wa of the workpiece W by supplying, to the front surface Wa of the workpiece W, the processing liquid L1 configured to form the resist film R. The coating and developing apparatus 2 (2A, 2B) may be further equipped with the drain line IL1 configured to drain the processing liquid L1 to the outside of the coating and developing apparatus 2 (2A) from the processing space S1 in which the processing by the processing liquid L1 in the resist film forming unit is performed; the exhaust line gL1 configured to exhaust the gas within the processing space S1 to the outside of the coating and developing apparatus 2 (2A); the drain line IL2 configured to drain, independently of the drain line ILL the processing liquid L2 to the outside of the coating and developing apparatus 2 (2A) from the processing space S2 in which the processing by the processing liquid L2 in the film removing unit is performed; and the exhaust line gL2 configured to exhaust, independently of the exhaust line gL1, the gas within the processing space S2 to the outside of the coating and developing apparatus 2 (2A). In this case, even if the processing liquid L2 configured to remove the film F contains a component that is undesirable to be mixed with the component of the processing liquid L1, the etching processing using the processing liquid L2 can be performed within the coating and developing apparatus 2 (2A).

The coating and developing apparatus 2 may be further equipped with a friction reducing film forming unit configured to form, on the rear surface Wb of the workpiece W after being processed by the foreign substance removing unit, a friction reducing film configured to reduce the friction between the rear surface Wb of the workpiece W and the portion holding the rear surface Wb of the workpiece W in the exposure processing. In this case, the workpiece W is loaded so as to be slid against the portion holding the rear surface Wb in the exposure processing. Thus, even if the peripheral portion of the workpiece W is bent downwards, the stress applied to the peripheral portion of the workpiece Win the exposure processing can be reduced.

The coating and developing apparatus 2A (2B) may be further equipped with a friction reducing film forming unit configured to form, on the rear surface Wb of the workpiece W before being processed by the film removing unit, a friction reducing film configured to reduce the friction between the rear surface Wb of the workpiece W and the portion holding the rear surface Wb of the workpiece W in the exposure processing. In this case, the workpiece W is loaded so as to be slid against the portion holding the rear surface Wb in the exposure processing. Thus, even if the peripheral portion of the workpiece W is bent downwards, the stress applied to the peripheral portion of the workpiece W in the exposure processing can be reduced.

In the coating and developing apparatus 2A (2B), the friction reducing film forming unit may form the friction reducing film at the peripheral portion of the rear surface Wb of the workpiece W. The film removing unit may perform the processing of removing a rear surface film on a region of the rear surface Wb of the workpiece W other than the peripheral portion. In this case, the area where the friction reducing film is formed is reduced as compared to the case where the friction reducing film is formed on the entire rear surface Wb. Further, it is not necessary to remove the rear surface film including the friction reducing film in the processing by the film removing unit. Therefore, the processing of forming the friction reducing film and the processing of removing the rear surface film can be simplified.

According to the present disclosure, it is possible to provide the substrate processing apparatus, the substrate processing method, and the recording medium capable of appropriately removing the foreign substance from the rear surface of the substrate on which the film is formed.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing apparatus, comprising:
a film processing unit configured to perform a preset processing including formation of a resist film on a front surface of a substrate; and
a carry-in/out unit configured to perform a carry-in/carry-out of the substrate into/from the film processing unit,
wherein the film processing unit comprises:
a resist film forming unit configured to form the resist film on the front surface of the substrate;
a film removing unit configured to supply, to a rear surface film formed on a rear surface of the substrate opposite to the front surface, a processing liquid configured to remove the rear surface film; and
a foreign substance removing unit configured to move a brush along the rear surface of the substrate, while keeping the brush in contact with the rear surface of the substrate after being processed by the film removing unit.

2. The substrate processing apparatus of claim 1,
wherein the brush is a cleaning brush,
the foreign substance removing unit polishes the rear surface of the substrate by moving a polishing brush, which is different from the cleaning brush, along the rear surface of the substrate, while keeping the polishing brush in contact with the rear surface of the substrate, and
after polishing the rear surface of the substrate, the foreign substance removing unit cleans the rear surface of the substrate by moving the cleaning brush along the rear surface of the substrate, while keeping the cleaning brush in contact with the rear surface of the substrate.

3. The substrate processing apparatus of claim 1,
wherein the film removing unit supplies the processing liquid to the rear surface of the substrate in a state that the substrate is held with the rear surface thereof facing downwards.

4. The substrate processing apparatus of claim 1,
wherein the foreign substance removing unit performs a processing of removing a foreign substance on the rear surface of the substrate in a state that the substrate is held with the rear surface thereof facing downwards.

5. The substrate processing apparatus of claim 1, further comprising:
an inverting unit configured to invert the rear surface of the substrate upside down,
wherein the foreign substance removing unit processes the substrate after being inverted by the inverting unit, and
the foreign substance removing unit performs a processing of removing a foreign substance on the rear surface of the substrate in a state that the substrate is held with the rear surface thereof facing upwards.

6. The substrate processing apparatus of claim 5,
wherein the film removing unit supplies the processing liquid to the rear surface of the substrate in a state that the substrate is held with the rear surface thereof facing downwards, and
the inverting unit inverts the rear surface of the substrate, which is obtained after being processed by the film removing unit, upside down.

7. The substrate processing apparatus of claim 6, further comprising:
a second inverting unit configured to invert the rear surface of the substrate, which is obtained after being processed by the foreign substance removing unit, upside down.

8. The substrate processing apparatus of claim 1,
wherein the film removing unit and the foreign substance removing unit process the rear surface of the substrate after the resist film is formed on the front surface of the substrate by the resist film forming unit and before the substrate is subjected to an exposure processing.

9. The substrate processing apparatus of claim 1,
wherein the film removing unit and the foreign substance removing unit process the rear surface of the substrate after the substrate is carried into the film processing unit and before the resist film is formed on the front surface of the substrate by the resist film forming unit.

10. The substrate processing apparatus of claim 1,
wherein the resist film forming unit forms the resist film on the front surface of the substrate by supplying, to the front surface of the substrate, another processing liquid configured to form the resist film, and
wherein the substrate processing apparatus further comprises:
a first drain line configured to drain the another processing liquid to an outside of the substrate processing apparatus from a first processing space in which a processing by the another processing liquid in the resist film forming unit is performed;
a first exhaust line configured to exhaust a gas within the first processing space to the outside of the substrate processing apparatus;
a second drain line configured to drain, independently of the first drain line, the processing liquid to the outside of the substrate processing apparatus from a second processing space in which a processing by the processing liquid in the film removing unit is performed; and
a second exhaust line configured to exhaust, independently of the first exhaust line, a gas within the second processing space to the outside of the substrate processing apparatus.

11. The substrate processing apparatus of claim 1, further comprising:
a friction reducing film forming unit configured to form, on the rear surface of the substrate after being processed by the foreign substance removing unit, a friction reducing film configured to reduce friction between the rear surface of the substrate and a portion holding the rear surface of the substrate in an exposure processing.

12. The substrate processing apparatus of claim 1, further comprising:
a friction reducing film forming unit configured to form, on the rear surface of the substrate before being processed by the film removing unit, a friction reducing film configured to reduce friction between the rear surface of the substrate and a portion holding the rear surface of the substrate in an exposure processing.

13. The substrate processing apparatus of claim 12,
wherein the friction reducing film forming unit forms the friction reducing film at a peripheral portion of the rear surface of the substrate, and
the film removing unit performs a processing of removing the rear surface film on a region of the rear surface of the substrate other than the peripheral portion.

14. A substrate processing method, comprising:
performing, in a film processing unit, a preset processing including formation of a resist film on a front surface of a substrate; and
performing a carry-in/carry-out of the substrate into/from the film forming unit,
wherein the preset processing includes:
forming the resist film on the front surface of the substrate;
supplying, to a rear surface film formed on a rear surface of the substrate opposite to the front surface, a processing liquid configured to remove the rear surface film; and
moving a brush along the rear surface of the substrate while keeping the brush in contact with the rear surface of the substrate after being subjected to the supplying of the processing liquid.

15. The substrate processing method of claim 14,
wherein the brush is a cleaning brush, and
wherein the moving of the brush along the rear surface of the substrate comprises:
polishing the rear surface of the substrate by moving a polishing brush, which is different from the cleaning brush, along the rear surface of the substrate, while keeping the polishing brush in contact with the rear surface of the substrate; and
cleaning, after the polishing of the rear surface of the substrate, the rear surface of the substrate by moving the cleaning brush along the rear surface of the substrate, while keeping the cleaning brush in contact with the rear surface of the substrate.

16. The substrate processing method of claim 14,
wherein, in the supplying of the processing liquid, the processing liquid is supplied to the rear surface of the substrate in a state that the substrate is held with the rear surface thereof facing downwards.

17. The substrate processing method of claim 14,
wherein, in the moving of the brush along the rear surface of the substrate, a foreign substance on the rear surface of the substrate is removed in a state that the substrate is held with the rear surface thereof facing downwards.

18. The substrate processing method of claim 14, further comprising:
inverting the rear surface of the substrate upside down by an inverting unit,
wherein, in the moving of the brush along the rear surface of the substrate, a processing is performed on the substrate after being inverted by the inverting unit, and
in the moving of the brush along the rear surface of the substrate, a foreign substance on the rear surface of the substrate is removed in a state that the substrate is held with the rear surface thereof facing upwards.

19. The substrate processing method of claim 18,
wherein, in the supplying of the processing liquid, the processing liquid is supplied to the rear surface of the substrate in a state that the substrate is held with the rear surface thereof facing downwards, and
the inverting of the rear surface of the substrate upside down by the inverting unit comprises inverting the rear surface of the substrate, which is obtained after being subjected to the supplying of the processing liquid, upside down by the inverting unit.

20. A computer readable recording medium having stored thereon computer-executable instructions that, in response to execution, cause an apparatus to perform a substrate processing method as claimed in claim 14.
